(19) United States
(12) Patent Application Publication
(10) Pub. No.: US 2026/0148936 A1
(43) Pub. Date: May 28, 2026

(54) HEAT FLOW CONTROL IN A PROCESSING TOOL

(71) Applicant: Lam Research Corporation, Fremont, CA (US)

(72) Inventors: Patrick G. BREILING, Tigard, OR (US); Harish Kumar PREMAKUMAR, Bangalore (IN); Timothy Scott THOMAS, Wilsonville, OR (US); Sairam SUNDARAM, Wilsonville, OR (US); Noah Elliot BAKER, West Linn, OR (US); Christopher GAGE, Truckee, CA (US); Aaron Blake MILLER, West Linn, OR (US); Ashish SAURABH, Portland, OR (US); Sudhir SRIVASTAVA, Lucknow (IN); Ramesh CHANDRASEKHARAN, Lake Oswego, OR (US); Naveen Kumar NAGAMALLAPPA, Bangalore (IN); Nitin KADAM, Dharwad (IN)

(73) Assignee: Lam Research Corporation, Fremont, CA (US)

(21) Appl. No.: 19/116,275

(22) PCT Filed: Oct. 11, 2023
(86) PCT No.: PCT/US2023/034976

§ 371 Date: Mar. 27, 2025

Related U.S. Application Data
(60) Provisional application No. 63/380,717, filed on Oct. 24, 2022.
(60) Provisional application No. 63/380,721, filed on Oct. 24, 2022.

(51) Int. Cl. H01J 37/32; H02N 13/00

(52) U.S. Cl. CPC H01J 37/32; H02N 13/00

(57) ABSTRACT

An apparatus comprises an electrostatic chuck including a plate electrode and a column structure coupled with the plate electrode. A disk is coupled with the electrostatic chuck where the disk includes a first hole in a center of the disk and a second hole and a third hole distributed through the disk, where a portion of the column structure extends through the first hole. The apparatus further includes retention structures, wherein the retention structures individually include a shaft and a nut coupled with the shaft and the disk. The shaft extends through the second hole or the third hole and couples with a surface of the plate electrode.

### CLAIM OF PRIORITY

This application claims priority to U.S. Provisional Ser. No. 63/380,717, filed on Oct. 24, 2022, titled “APPARATUS FOR CONTROLLING HEAT FLOW IN A PROCESSING TOOL,” and to U.S. Provisional Ser. No. 63/380,721, filed on Oct. 24, 2022, titled “APPARATUS FOR DIVERTING HEAT FLOW IN A PROCESSING TOOL,” and which are incorporated by reference in entirety.

### BACKGROUND

Substrate processing for etch and deposition form the backbone of the semiconductor industry. While a variety of plasma processing techniques may be utilized, virtually all processes utilize a plate electrode where a semiconductor wafer is placed during etching and deposition. Depending on the nature of the process (deposition or etch), a plate electrode may be heated to enable chemicals to be deposited or to enhance etching. While heating can be important for the process, directing unwanted heat safely away from the vicinity of the plate electrode is desirable. As such, methods are being investigated to accomplish effective heat transfer.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Also, various physical features may be represented in their simplified “ideal” forms and geometries for clarity of discussion, but it is nevertheless to be understood that practical implementations may only approximate the illustrated ideals. For example, smooth surfaces and square intersections may be drawn in disregard of finite roughness, corner-rounding, and imperfect angular intersections, characteristic of structures formed by nanofabrication techniques. Further, where considered appropriate, reference labels have been repeated among the figures to indicate corresponding or analogous elements.

FIG. 1A is a cross-sectional illustration of an electrostatic chuck including stem pieces coupled by an o-ring, in accordance with an implementation of the present disclosure.

FIG. 1B is an isometric illustration of the electrostatic chuck including stem pieces coupled by an o-ring, in accordance with an implementation of the present disclosure.

FIG. 2A is a cross-sectional illustration of an apparatus including an electrostatic chuck coupled with a heat shield, in accordance with an implementation of the present disclosure.

FIG. 2B is an isometric illustration of the apparatus in FIG. 2A, in accordance with an implementation of the present disclosure.

FIG. 2C is a plan view illustration of the heat shield in FIG. 2A, in accordance with an implementation of the present disclosure.

FIG. 2D is a cross-sectional illustration of a heat shield, in accordance with an implementation of the present disclosure.

FIG. 2E is a cross-sectional illustration of a heat shield coupled with a plate electrode of an electrostatic chuck, in accordance with an implementation of the present disclosure.

FIG. 2F is a cross-sectional illustration of a heat shield, in accordance with an implementation of the present disclosure.

FIG. 3A is an illustration of a shaft, in accordance with an implementation of the present disclosure.

FIG. 3B is a cross-sectional illustration of the shaft in FIG. 3A, in accordance with an implementation of the present disclosure.

FIG. 3C is an isometric illustration of a portion of the shaft in FIG. 3A, in accordance with an implementation of the present disclosure.

FIG. 4 is a cross-sectional illustration of a heat shield coupled to a plate electrode with a nut and the shaft illustrated in FIG. 3B, in accordance with an implementation of the present disclosure.

FIG. 5 is a cross-sectional illustration of a heat shield coupled to a plate electrode with the nut and shaft, in accordance with an implementation of the present disclosure.

FIG. 6 is a plan-view illustration of a heat shield, in accordance with an implementation of the present disclosure.

FIG. 7A is an isometric illustration of an apparatus including the heat shield in FIG. 6, in accordance with an implementation of the present disclosure.

FIG. 7B is a cross-sectional illustration of the apparatus in FIG. 7A, in accordance with an implementation of the present disclosure.

FIG. 8 is a cross-sectional illustration of an apparatus including an electrostatic chuck coupled with a first heat shield and a second heat shield below the first heat shield, in accordance with an implementation of the present disclosure.

FIG. 9A is a cross-sectional illustration of an apparatus including an electrostatic chuck coupled with a shield, in accordance with an implementation of the present disclosure.

FIG. 9B is an isometric illustration of the apparatus in FIG. 9A, in accordance with an implementation of the present disclosure.

FIG. 9C is the isometric illustration in FIG. 9B where portions of the shield are cut out to reveal a column structure and clamps, in accordance with an implementation of the present disclosure.

FIG. 10A is a cross-sectional illustration of an apparatus including an electrostatic chuck coupled with a cap shield, in accordance with an implementation of the present disclosure.

FIG. 10B is an isometric illustration of the apparatus in FIG. 10A, in accordance with an implementation of the present disclosure.

FIG. 10C is the isometric illustration in FIG. 10B where portions of the shield are cut out to reveal a column structure and clamps, in accordance with an implementation of the present disclosure.

FIG. 11 is a cross-sectional illustration of a heat shield coupled to a shield, in accordance with an implementation of the present disclosure.

FIG. 12 is a cross-sectional illustration of an apparatus that includes multi-layer heat shield structure, in accordance with at least one implementation.

### DETAILED DESCRIPTION

An apparatus for controlling heat flow in a process tool is described. In the following description, numerous specific details are set forth, such as structural schemes to provide a thorough understanding of implementations of the present disclosure. It will be apparent to one skilled in the art that implementations of the present disclosure may be practiced without these specific details. In other instances, well-known features, such as radio frequency sources, are described in lesser detail to not unnecessarily obscure implementations of the present disclosure. Furthermore, it is to be understood that the various implementations shown in the Figures are illustrative representations and are not necessarily drawn to scale.

In some instances, in the following description, well-known methods and devices are shown in block diagram form, rather than in detail, to avoid obscuring the present disclosure. Reference throughout this specification to “an implementation” or “one implementation” or “some implementations” means that a particular feature, structure, function, or characteristic described in connection with the implementation is included in at least one implementation of the disclosure. The appearances of the phrase “in an implementation” or “in one implementation” or “some implementations” in various places throughout this specification are not necessarily referring to the same implementation of the disclosure. Furthermore, the particular features, structures, functions, or characteristics may be combined in any suitable manner in one or more implementations. For example, a first implementation may be combined with a second implementation anywhere the particular features, structures, functions, or characteristics associated with the two implementations are not mutually exclusive.

Here, “coupled” and “connected,” along with their derivatives, may describe functional or structural relationships between components. These terms are not intended as synonyms for each other. Rather, in at least one implementation, “connected” may be used to indicate that two or more elements are in direct physical, optical, or electrical contact with each other. “Coupled” may be used to indicate that two or more elements are in either direct or indirect (with other intervening elements between them) physical, electrical or magnetic contact with each other, and/or that the two or more elements co-operate or interact with each other (e.g., as in a cause-and-effect relationship).

Here, “over,” “under,” “between,” and “on” may generally refer to a relative position of one component or material with respect to other components or materials where such physical relationships are noteworthy. Unless these terms are modified with “direct” or “directly,” one or more intervening components or materials may be present. Similar distinctions are to be made in the context of component assemblies. As used throughout this description, and in the claims, a list of items joined by the term “at least one of” or “one or more of” can mean any combination of the listed terms.

Here, “adjacent” may generally refer to a position of a thing being next to (e.g., immediately next to or close to with one or more things between them) or adjoining another thing (e.g., abutting it).

Unless otherwise specified in the explicit context of their use, the terms “substantially equal,” “about equal,” and “approximately equal” mean that there is no more than incidental variation between two things so described. In the art, such variation is typically no more than +/−10% of the referred value.

Processing tools are utilized to accomplish a variety of deposition and etch processes in semiconductor device manufacturing. Processing tools can include one or more electrostatic chucks for single wafer processing or multi-wafer processing capabilities for batch processing. Here, the term “electrostatic chuck” may generally refer to a plate electrode coupled with a stem. The electrostatic chuck may include heating and/or cooling elements that are included to aid in processing of substrates. The electrostatic chuck may be coupled with a radio frequency power supply.

Here, “plate electrode” may generally refer to a flat disk structure that is utilized to support a substrate to be processed. In at least one implementation, plate electrode can be coupled with various components within the tool such as cooling gas lines, pusher pins, radio frequency lines, heating electrodes, etc. Plate electrodes may be attached to a column structure that can house one or more components. Here, “column structure” may generally refer to a cylindrical tube that is connected with the plate electrode. The cylindrical tube may be hollow to provide a conduit for one or more electrical and gas lines that may couple with plate electrode. The column structure may include one or more tubes or stem pieces that are coupled together. Here, “stem” may generally refer to a supporting structure. The stem may be a thermal conductor.

To facilitate parts exchange, the column structure may include a primary stem piece that is connected with the plate electrode and an adjoining secondary stem piece that is coupled with the primary stem piece. Such coupling may be accomplished by joining the primary and the secondary stem pieces with clamps, and/or nonmetallic components such as ceramic separators, and o-rings. O-rings may be used to provide a seal between the primary and secondary stem pieces.

Here, “clamp” may generally refer to a structure that couples two separate pieces together. The clamp may be thermally conductive.

Plate electrodes are typically utilized in plasma etching and in some deposition processes. Such processes can require high processing temperature (temperatures above 300 degrees Celsius may be referred to as high temperature) to create favorable conditions for etching and/or deposition. High temperatures may be generated by heating a plate electrode and/or by plasma generated within a chamber housing the plate electrode. Filamentary heating may be utilized to heat plate electrode to raise temperatures of process wafers or substrates. While high processing temperature can be beneficial, heat generated from the vicinity of the plate electrode can transport heat to portions of the plate electrode leading to degradation of parts. In at least one implementation, heat generated is directed away from lower portions of the plate electrode to the chamber walls.

During operation of the processing tool, heat can transfer from the plate electrode (of the electrostatic chuck) towards the primary column structure connected to the plate electrode and reach the non-metallic components such as o-rings. Unwanted heating of o-rings can cause them to become degraded. Degradation of o-rings can introduce leaks and particles into the chamber. Leaks and particles can lead to processing degradation and loss of functionality of devices fabricated on semiconductor substrates, for example.

While heat conduction from the plate electrode is one mechanism of heat transfer, another mechanism includes thermal radiation from under the plate electrode to the connected column structure. Diverting heat from the plates towards chamber walls is used to prevent heat from reaching components such as an o-ring.

Plate electrode may be rapidly cooled between processing of single substrates. In at least one implementation, radiative heat transfer is reduced to non-metallic components during operation. Heat radiated from the plate electrode may be at least partially prevented from reaching portions of the primary stem piece and clamp by insertion of a heat shield. The heat shield may be inserted between the plate electrode and the clamp (covering the o-ring). Here, “heat shield” may generally refer to a planar or a non-planar thermally conductive structure. The heat shield may be solid metallic, perforated, or comprise large openings. In some implementations, the heat shield may be a disk with two or more holes. The structure of the heat shield may depend on processing conditions such as temperature, duration of process, and on processing chemistry utilized, etc. The structure (for example, shape, size, and composition) of the heat shield may also depend on the shape and size of the plate electrode.

To facilitate removal and servicing of components such as o-rings, the heat shield can be mounted directly under the plate electrode. To practically realize radiative heat transfer, the heat shield is separated from the surface of the plate electrode by a minimum separation distance. The separation distance between the heat shield and the plate electrode may depend on the structure of the heat shield and on processing conditions. In some implementations, the separation distance can be at least one inch.

The retention structure may include two or more components that are coupled together with the heat shield, for example, customized nuts and bolts. The retention structure may be a thermal conductor.

It may be advantageous to mount the heat shield to specific locations on the plate electrode for enhanced flexibility. For practical purposes, the heat shield can be mounted to a surface of the plate electrode that is facing the heat shield using one or more retention structures. Here, the term “retention structure” may generally refer to a support structure that provides mechanical support and enables coupling of the heat shield. The retention structure may penetrate through one or more openings in the heat shield. Examples of locations include locations in and around the vicinity of pusher pins. Pusher pins are utilized in an electrostatic chuck to enable lowering and raising of substrates from the surface of plate electrodes before and after processing. In at least one implementation, a retention structure is provided to accommodate inclusion of pusher pins. In some implementations, the heat shield can be mounted using nuts and bolts. The bolts may include structural features such as multiple threaded and non-threaded portions and cavities. Here, “threaded” or “threaded portion” may generally refer to an object or a portion of an object having a screw thread on an outer perimeter. In other examples, the bolts may include an attached ring at a certain length to set a predetermined separation distance between the heat shield and the plate electrode.

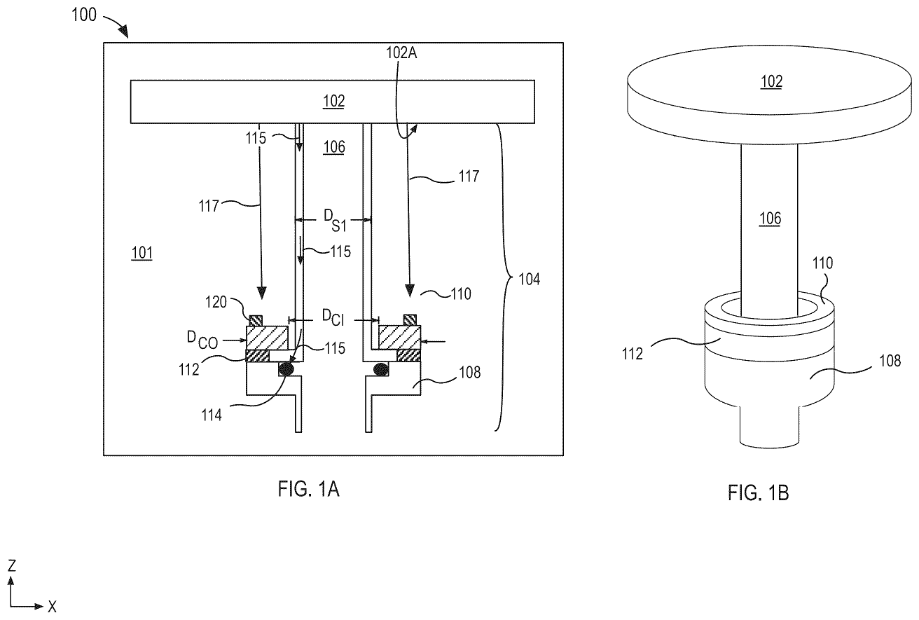

FIG. 1A is a cross-sectional illustration of an electrostatic chuck 100 within chamber 101, in accordance with at least one implementation. In at least one implementation, electrostatic chuck 100 includes plate electrode 102 and column structure 104 coupled with plate electrode 102. In at least one implementation, column structure 104 may be fabricated as part of the plate electrode 102, or separately but coupled with plate electrode 102 during assembly of electrostatic chuck 100. In at least one implementation, column structure 104 may be limited to stem 106. In at least one implementation, column structure 104 includes stem 106 and stem 108. Stem 106 and stem 108 may be coupled together by clamp 110, insulator ring 112 and o-ring 114. In at least one implementation, o-ring 114 may be between stems 106 and 108. Here, “stem” may generally refer to a hollow cylindrical object. Stems 106 and 108 may include a thermally conductive material. In at least one implementation, stems 106 and 108 include a same material. In some implementations, stems 106 and 108 may include the same material as a material of plate electrode 102. In some such implementations, stem 106 may be contiguous with plate electrode 102.

Here, “o-ring” may generally refer to a polymer-based ring structure that is used to seal an interface between two relatively flat surfaces. Here, “insulator ring” may generally refer to a ring fashioned from a non-electrically conductive material. The insulator ring may conduct heat to a level that is lower than a thermal conductivity of a metal.

During operation of electrostatic chuck 100, heat generated at plate electrode 102 may be transported to column structure 104 by both conduction (denoted by arrows 115) and thermal radiation (denoted by arrows 117). As shown, heat emanates from surface 102A of plate electrode 102. Heat impinging on stem 106 can be transported to o-ring 114 and insulator ring 112. During operation, heat transport can cause temperature in the vicinity of clamp 110 to reach over 350 degrees Celsius. Prolonged exposure at temperatures of 350 degrees Celsius or more can cause structural degradation of o-ring 114. Structural degradation of o-ring 114 can cause vacuum leaks, and more importantly, contaminants can escape to chamber 101 during operation. Such contaminants can cause degradation of substrates that are placed in electrostatic chuck 100 during processing. Column structure 104 is designed to facilitate removal of o-ring 114. Clamp 110 may be released by removing clamp bolts 120 and insulator ring 112. Frequent unscheduled removal of components (o-ring 114, insulator ring 112, etc.) can result in downtime of processing tool. In at least one embodiment, one or mor components are provided that mitigate heat at clamp 110 and o-ring 114.

Clamp 110 has an inner diameter D_{CI} and an outer diameter D_{CO}, and stem 106 has a diameter D_{S1}. Heat mitigation structures (for example heat shields) are designed with reference to these parameters.

FIG. 1B is an isometric illustration of the structure in FIG. 1A. In at least one implementation, column structure 104, stem 106, stem 108, clamp 110, and insulator ring 112 are cylindrical or substantially cylindrical, and plate electrode 102 has the shape of a circular disk. In at least one implementation, circular disk shape is typical of electrostatic chuck 100 utilized to process semiconductor substrates. Here, “disk” may generally refer to an area bounded by a circle.

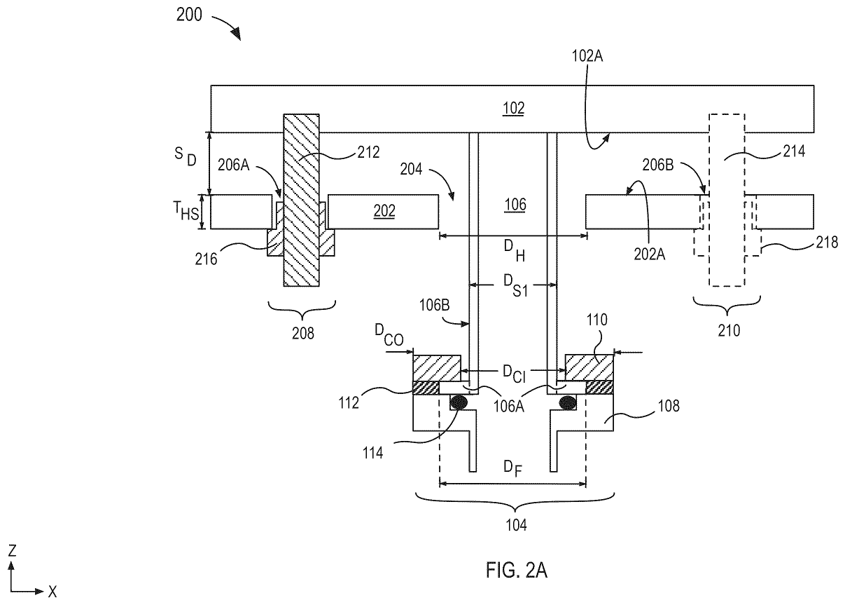

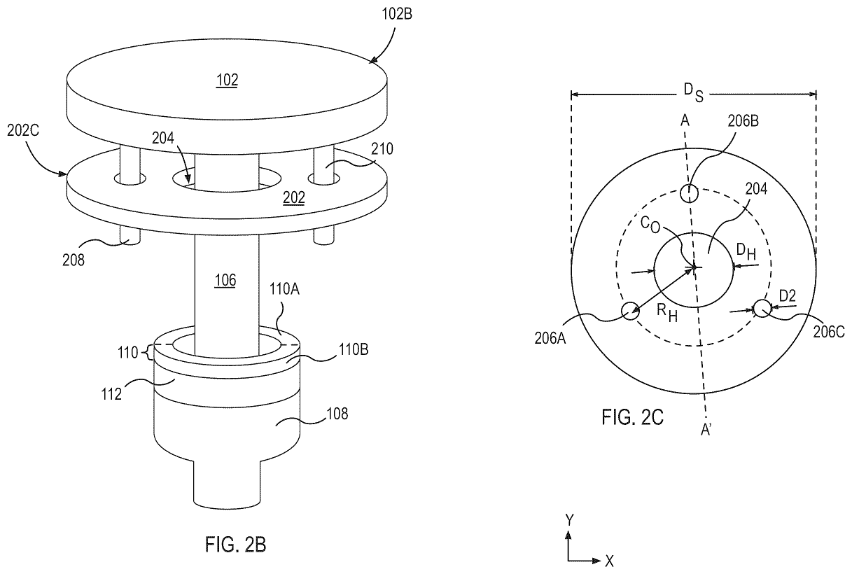

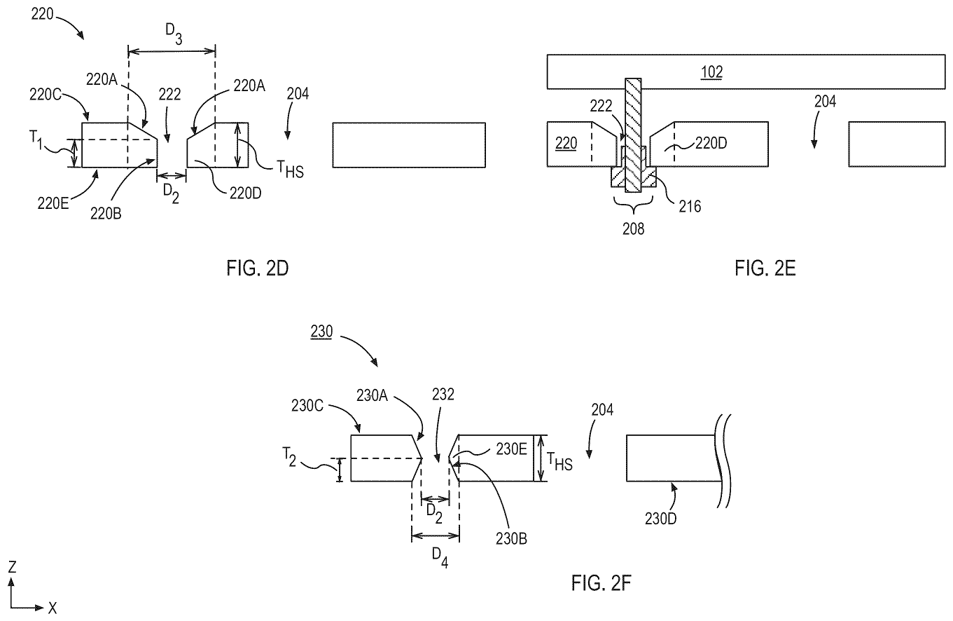

FIG. 2A is a cross-sectional illustration of apparatus 200 that includes electrostatic chuck 100 (illustrated in FIG. 1A) and heat shield 202, in accordance with at least one implementation. In at least one implementation, heat shield 202 is coupled with plate electrode 102. In at least one implementation, heat shield 202 may have different plan view shapes, such as disk, square, rectangle, etc. In at least one implementation, heat shield 202 may be a disk. In at least one implementation, heat shield 202 includes hole 204 at center of heat shield 202. The center is an axial center when heat shield 202 is a disk. In at least one implementation, a portion of column structure 104 extends through hole 204. In at least one implementation, heat shield 202 further includes holes 206A and 206B distributed through heat shield 202. In at least one implementation, apparatus 200 further includes retention structure 208 and retention structure 210 to couple heat shield 202 with plate electrode 102. Retention structure 208 includes shaft 212, and retention structure 210 includes shaft 214. In at least one implementation, portions of shafts 212 and 214 extend through holes 206A and 206B, respectively, and couple with surface 102A of plate electrode 102.

Here, “shaft” may generally refer to a cylindrical bolt-like structure with two or more threaded portions. In at least one implementation, a shaft may include a channel extending along a length of the shaft for insertion of other components.

In at least one implementation, retention structure 208 further includes nut 216 coupled with shaft 212 and retention structure 210 further includes nut 218 coupled with shaft 214. In at least one implementation, nuts 216 and 218 provide mechanical support for heat shield 202. Here, “nut” may generally refer to hollow cylindrical threaded structure that can couple with threaded portions of a bolt-like structure. In at least one implementation, heat shield 202 is in contact with at least nuts 216 and 218. In at least one implementation, portions of shafts 212 and 214 can be in contact with heat shield 202, as will be discussed later.

In at least one implementation, holes 206A and 206B are superimposed on the same cross-sectional plane. In at least one implementation, cross-sectional plane may lie along a diameter where heat shield 202 has a circular plan view profile. Holes 206A and 206B are shown in the same plane for illustrative purposes. Positions of holes 206A and 206B are discussed below. In at least one implementation, heat shield 202 comprises thickness T_{HS}. Thickness T_{HS} may range between 10 mm and 20 mm to provide sufficient heat absorption.

As discussed previously, thermal radiation emanating from surface 102A can reach clamp 110. The amount of thermal radiation reaching clamp 110 may depend on several factors. In at least one implementation, factors include size of hole 204 relative to width of stem 106 and relative position of heat shield 202 relative to surface 102A and clamp 110. In at least one implementation, size of hole 204 relative to width of stem 106 may influence an angle between hole 204 and a portion of surface 102A directly above hole 204. In at least one implementation, angle may at least depend on separation distance S_{D} between surface 202A of heat shield 202 and surface 102A. In at least one implementation, stem 106 blocks some of the thermal radiation reaching clamp 110. In at least one implementation, size of hole 204 relative to the width of stem 106 may also determine total thermal radiation flux. In at least one implementation, relative size of hole 204 with respect to clamp 110 can also partially determine total thermal radiation absorbed by clamp 110. In at least one implementation, hole 204 may be large enough to expose portions of clamp 110 at least partially.

In at least one implementation, hole 204, clamp 110, and stem 106 are circular. In at least one implementation, hole 204 has diameter D_{H}, cylindrical portion of stem 106 has diameter D_{S1}, and clamp 110 has inner diameter D_{CI} and outer diameter D_{CO}. In at least one implementation, diameter D_{H} of hole 204 relative to diameter D_{S1} of a cylindrical portion of stem 106 may partially determine a total amount of thermal radiation reaching clamp 110. In at least one implementation, a difference between inner diameter D_{CI} and diameter D_{H} may also partially determine a total amount of thermal radiation reaching clamp 110. In at least one implementation, inner diameter D_{CI} is greater than diameter D_{S1} to prevent direct thermal contact with sidewall 106B of stem 106. There may be a separation of at least 1 mm between diameter D_{CI} and diameter D_{S1}. In at least one implementation, for practical considerations, diameter D_{H} can be wider than diameter D_{CO}. In at least one implementation, column structure 104 where stem 106 is separable from plate electrode 102.

However, by making modifications to clamp 110, in at least one implementation, where stem 106 is attached to plate electrode 102, diameter D_{H} can be between inner diameter D_{CI} and outer diameter D_{CO}. In at least one implementation, where stem 106 is inseparable from plate electrode 102, diameter D_{H} may be at least greater than diameter D_{F} of base flange 106A. In at least one implementation, diameter D_{H} can be comparable or even smaller than diameter D_{F} with modifications in design of clamp 110. Examples of modifications in clamp 110 are discussed below.

In at least one implementation, diameter D_{H} can range between 50 mm and 100 mm. In at least one implementation, diameter D_{S1} can range between 30 mm and 75 mm, and diameter D_{F} can range between 50 mm and 100 mm. In at least one implementation, diameters D_{CO} and D_{CI} can range between 40 mm and 150 mm. In at least one implementation, depending on separation distance S_{D} and diameters D_{H}, D_{S1}, and D_{CI}, heat shield 202 can reduce temperature at clamp 110 by at least 20%.

FIG. 2B is an isometric illustration of apparatus 200, in accordance with at least one implementation. In at least one implementation, heat shield 202 is a disk. Plate electrode 102 has a circular shape to provide uniform process conditions for a circular substrate. In at least one implementation, column structure 104, clamp 110, insulator ring 112, stems 106 and 108, and hole 204 are substantially circular. In the illustrative implementation, holes 206A and 206B do not lie along a diameter (as will be discussed below).

In at least one implementation, to provide adequate heat deflection and absorption, heat shield 202 may be similarly sized as plate electrode 102. Heat shield 202 has perimeter 202C. In at least one implementation, such as is shown, perimeter 202C is substantially aligned with perimeter 102B of plate electrode 102.

In at least one implementation, clamp 110 may comprise two separate portions, such as portion 110A and portion 110B illustrated by dashed lines. Implementation of separate portions 110A and 110B can advantageously reduce a size of hole 204 compared to a size of diameter of clamp 110. In at least one implementation, hole 204 can have a size that is at least greater than a size of base flange 106A of stem 106 (illustrated in FIG. 2A).

FIG. 2C is a plan view illustration of heat shield 202, described in association with FIG. 2B, in accordance with at least one implementation. In at least one implementation, heat shield 202 may have a circular cross section. In at least one implementation, hole 204 may be substantially circular and may be coaxial with a perimeter of heat shield 202.

In at least one implementation, hole 206C is visible in the plan-view illustration. As configured, holes 206A, 206B, and 206C may be substantially equidistant from an axial center C_{O}, of heat shield 202. In at least one implementation, holes 206A, 206B, and 206C may be arranged at a respective apex of an equilateral triangle. In at least one implementation, holes 206A, 206B, and 206C may be uniformly spaced apart from each other. In at least one implementation, relative position between holes 206A, 206B, and 206C may be designed to advantageously provide access to pusher pins that are utilized in lifting substrates from electrostatic chuck 100. In at least one implementation, holes 206A, 206B, and 206C may be located at radius R_{H}, from center of hole 204. In at least one implementation, radius R_{H} may be less than half of diameter D_{S} of heat shield 202.

In at least one implementation, holes 206A, 206B, and 206C can have a substantially same diameter or have different diameters. In at least one implementation, holes 206A, 206B, and 206C have substantially same diameter D₂. In at least one implementation, diameter D₂ can range between 12 mm and 50 mm. In at least one implementation, diameter D_{H} is substantially greater than diameter D₂.

In at least one implementation, region surrounding holes 206A, 206B, and 206C may have a variable diameter along a thickness of heat shield 202. In at least one implementation, holes 206A, 206B, and 206C may be slanted or stepped.

FIG. 2D is a cross sectional illustration of heat shield 220 through a diameter of heat shield 220, in accordance with at least one implementation. In at least one implementation, heat shield 220 includes one or more features of heat shield 202 such as holes 204.

In at least one implementation, diameter dissects hole 204 and hole 222. In at least one implementation, hole 222 may have a variable diameter along thickness T_{HS}. In at least one implementation, heat shield 220 includes surfaces 220A and sidewalls 220B within hole 222. In at least one implementation, surfaces 220A may be slanted with respect to surface 220C of heat shield 220 and sidewalls 220B are vertical with respect to surface 220C. In at least one implementation, surface 220C may be a top surface of heat shield 220. In at least one implementation, hole 222 may have maximum diameter D₃ and is tapered to diameter D₂, where diameter D₃ is greater than diameter D₂.

In at least one implementation, portion 220D of heat shield 202 below surface 220A can be advantageous from a thermal conductivity distribution standpoint. In at least one implementation, features such as portion 220D can advantageously limit conductive heat transfer from plate electrode 102. In at least one implementation, portion 220D can serve as pinch points, or locations where thermal conductivity is reduced between surfaces 220A and 220E. In at least one implementation, thermal conductivity may be reduced due to reduction in mass of the conductive material comprising heat shield 220.

In at least one implementation, diameter D₃ may be between 12 mm and 75 mm. Sidewalls 220B may have thickness T₁ relative to surface 220E. In at least one implementation, surface 220E is a bottom surface of heat shield 220. In at least one implementation, thickness T₁ may be between 10 and 50% of thickness T_{HS}.

FIG. 2E is a cross-sectional illustration of heat shield 220 (in FIG. 2D) coupled with plate electrode 102 by retention structure 208, in accordance with at least one implementation. In at least one implementation, heat shield 220 may be designed to be thermally coupled to a surrounding environment. In at least one implementation, heat shield 220 is designed to absorb thermal radiation at least partially.

In at least one implementation, portion 220D within hole 222 has a variable thickness. In at least one implementation, a variable thickness may limit conductive heat transfer between plate electrode 102 and heat shield 220 through retention structure 208. By limiting conductive heat transfer, thermal stresses induced by a thermal gradient vertically (Z-direction) across heat shield 220 may be reduced.

FIG. 2F is a cross sectional illustration of heat shield 230, in accordance with at least one implementation. In at least one implementation, heat shield 230 includes one or more features of heat shield 202 such as hole 204. In at least one implementation, heat shield 230 further includes two or more holes for coupling with plate electrode 102 (not shown). In at least one implementation, one hole such as hole 232 is shown in the diametrical cross section. In at least one implementation, hole 232 is utilized as a through hole for a retention structure such as retention structure 208 (FIG. 2E).

In at least one implementation, hole 232 has a variable diameter across thickness T_{HS}. In at least one implementation, heat shield 230 comprises a first tapered sidewall (herein tapered sidewall 230A) and a second tapered sidewall (herein tapered sidewall 230B). Here, “tapered sidewall” may generally refer to a non-vertical sidewall. In at least one implementation, sidewall may have a single slope or have different portions with different slopes that gradually increase in angle, where the angles are measured relative to a vertical plane. In at least one implementation, tapered sidewall 230A extends from surface 230C to thickness T₂ (relative to surface 230D) of heat shield 230 and tapered sidewall 230B extends from surface 230D to thickness T₂. In at least one implementation, thickness T₂ is approximately at a midplane of heat shield 230. In at least one implementation, a midplane is a plane at a mid-point of thickness T_{HS}. In at least one implementation, tapered sidewalls 230A and 230B may be oppositely directed as shown.

In at least one implementation, hole 232 has diameter D₄ and is tapered to diameter D₂, where diameter D₄ is greater than diameter D₂. In at least one implementation, diameter D₂, of hole 232 is the same or substantially the same as the diameter of hole 222 (FIG. 2E). In at least one implementation, diameter D₂ is of a sufficient width to insert a shaft and nut to couple heat shield 230 with a plate electrode. In at least one implementation, diameter D₄ may be between 12 mm and 50 mm. In at least one implementation, diameters D₂ and D₄ are designed to provide a sufficient gap between nut and heat shield 230 to accommodate expansion of heat shield 230. In at least one implementation, diameter D₄ may be less than an outer diameter of a nut (such as nut 216 illustrated in FIG. 2E).

In at least one implementation, portion 230E of heat shield 230 between surfaces 230C and 230D can be advantageous from a thermal conductivity distribution standpoint. In at least one implementation, portion 230E can serve as pinch points, or locations where thermal conductivity is reduced between surfaces 230C and 230D. In at least one implementation, thermal conductivity may be reduced due to reduction in mass of the conductive material comprising heat shield 230.

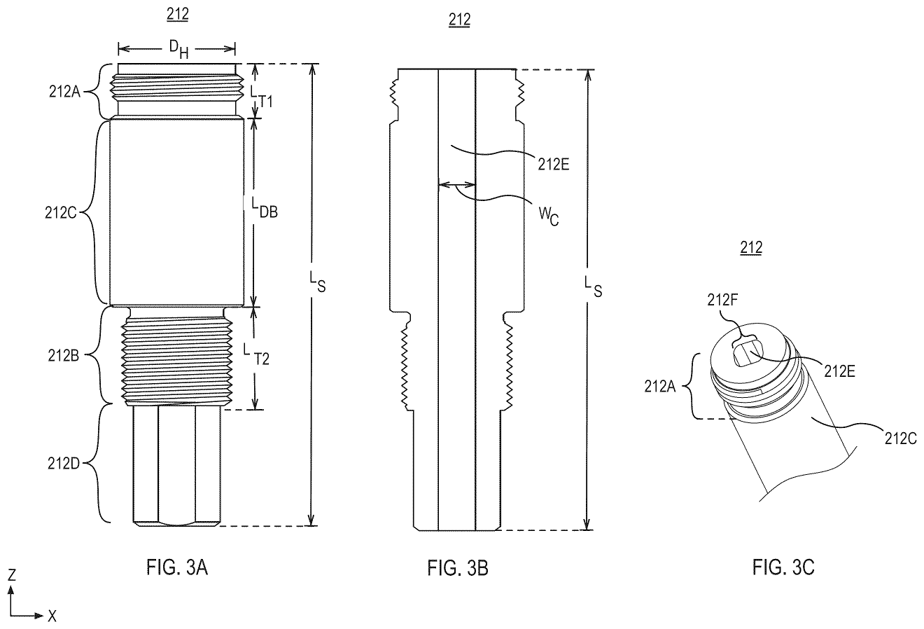

FIG. 3A is an illustration of shaft 212, in accordance with at least one implementation. In at least one implementation, shaft 212 has variable outer diameter D_{H} along length L_{S}. Shaft 212 includes first threaded portion 212A (herein, threaded portion 212A) and second threaded portion 212B (herein, threaded portion 212B). In at least one implementation, shaft 212 further includes barrel 212C positioned between threaded portions 212A and 212B. Here, “barrel” may generally refer to a portion of shaft 212 that determines a space between plate electrode and heat shield or between two heat shields. In at least one implementation, barrel 212C may not have threads. Barrel 212C has length L_{DB}, that is designed to substantially match a spacing between a plate electrode surface and a surface of a heat shield. In at least one implementation, length L_{DB} can be tuned depending on the desired electrode plate to heat shield spacing. In at least one implementation, length L_{DB} is at least 3 mm.

In at least one implementation, shaft 212 further includes end portion 212D adjacent to threaded portion 212B. In at least one implementation, end portion 212D has a length that is advantageously purposed for positioning and threading a nut during assembly of a heat shield.

While shaft 212 includes barrel 212C, in at least one implementation, barrel 212C may be replaced by a threaded portion. In at least one implementation, threaded portion may have a diameter that is same or different from diameter of threaded portions 212A and 212B. In at least one implementation, shaft 212 comprises a conductive material. Examples of conductive material include AlN, Al₂O₃, Ni—Co alloys, and Ni—Cr alloys.

FIG. 3B is a cross-sectional illustration through a diameter of shaft 212, in accordance with at least one implementation. In at least one implementation, shaft 212 includes hollow core 212E that extends length L_{S} of shaft 212. Here, “hollow core” may generally refer to a channel that extends within a structure such as shaft 212. In at least one implementation, core can be variable widths along the length. Hollow core 212E may be designed to accommodate a pusher pin utilized in lifting and lowering substrates onto a plate electrode. In at least one implementation, hollow core 212E has width, W_{C} that is substantially the same along length L_{S}, as shown. In at least one implementation, width W_{C} may be variable along length L_{S}.

FIG. 3C is an isometric illustration of shaft 212, according to at least one implementation. An isometric profile of hollow core 212E is shown in the illustration. In at least one implementation, hollow core 212E has an opening 212F that is substantially rectangular. In other implementations, opening 212F is substantially circular or elliptical. Features and properties of shaft 212 described in association with FIGS. 3A-3B also extend to shaft 214 described in association with FIG. 2A.

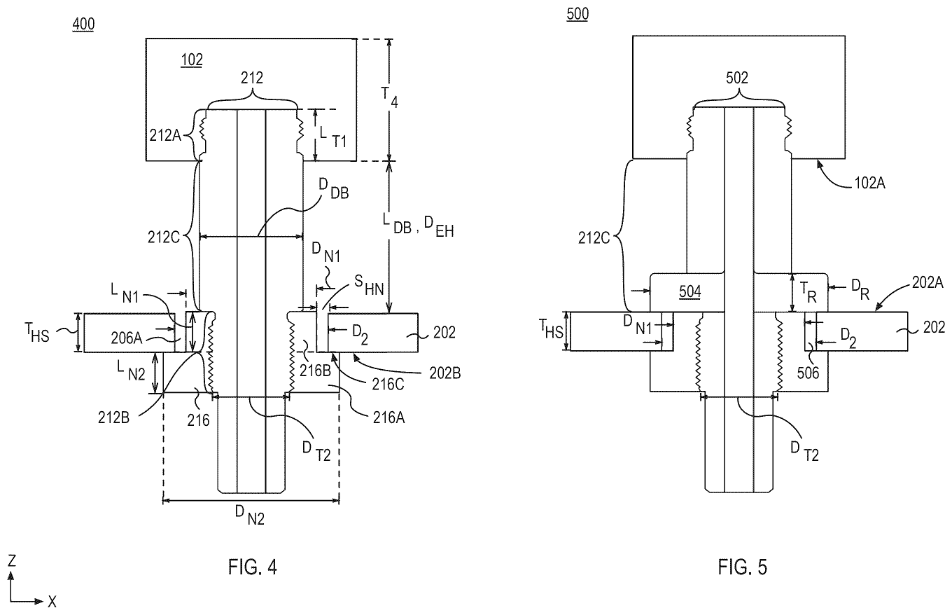

FIG. 4 is a cross-sectional illustration 400 of a portion of FIG. 2A, in accordance with at least one implementation. In at least one implementation, threaded portion 212A extends into plate electrode 102. In at least one implementation, threaded portion 212A has length, L_{T1}, that is less than thickness, T₄ of plate electrode 102. In at least one implementation, a portion of threaded portion 212B is adjacent to heat shield 202.

In at least one implementation, nut 216 is coupled with shaft 212 through threaded portion 212B. Nut 216 may have an outer diameter that varies with length of the nut. In at least one implementation, a portion of nut 216 may be utilized to support heat shield 202. In at least one implementation, nut 216 includes two contiguous portions, 216A and 216B where portions 216A and 216B have different outer diameters and different lengths.

In at least one implementation, portion 216A comprises outer diameter D_{N1} and length L_{N1}. In at least one implementation, portion 216B comprises outer diameter D_{N2} and length L_{N2}. Outer diameters D_{N1} and D_{N2} can be chosen depending on an extent of overlap desired between nut 216 and heat shield 202. In at least one implementation, outer diameter D_{N2} is greater than outer diameter D_{N1}.

In at least one implementation, nut 216 may have a length that may be dependent on thickness T_{HS}. In at least one implementation, length L_{N1} of portion 216A may be chosen to accommodate thickness T_{HS}. In at least one implementation, surface 202B is in contact with surface 216C of nut 216 in the vicinity of hole 206A. In at least one implementation, amount of overlap between surfaces 202B and 216C can range between 1 mm and 12 mm. In at least one implementation, overlap provides mechanical support for heat shield 202 to remain fastened to plate electrode 102.

In at least one implementation, hole 206A may be larger than portion 216A. In at least one implementation, hole 206A has diameter D₂ that may be greater than diameter D_{N1}. In at least one implementation, diameter D₂ is greater than diameter D_{N1} by at least 2 mm. In at least one implementation, spacing S_{HN} between heat shield 202 and nut portion 216A provides sufficient space for heat shield 202 to undergo thermal expansion without torquing shaft 212.

In at least one implementation, separation distance D_{EH} between plate electrode 102 and heat shield 202 can be chosen on processing temperatures and extent of heat mitigation required. In at least one implementation, separation distance D_{EH} is substantially equal to length L_{DB}. In at least one implementation, length L_{DB} represents a minimum distance between plate electrode 102 and heat shield 202. In at least one implementation, barrel 212C has an outer diameter D_{DB} that is greater than diameter D_{T2} of threaded portion 212B. Implementations where outer diameter D_{DB} is greater than diameter D_{T2} can help to prevent nut 216 from arbitrarily moving up shaft 212. In at least one implementation, shaft 212 also includes a ring attached to a body of shaft 212 to provide a guide for uniform spacing of heat shield 202 away from surface 202B.

FIG. 5 is a cross-sectional illustration 500 of the structure in FIG. 4 where shaft 502 includes ring 504, in accordance with at least one implementation. Here, “ring” may generally refer to a circular object having an annular shape. Shaft 502 includes many of the features of shaft 214 (FIG. 4). In at least one implementation, ring 504 is coupled with barrel 212C. In at least one implementation, ring 504 surrounds and is attached to a lower portion of barrel 212C, above threaded portion 212B. In at least one implementation, ring 504 may be attached to body of shaft 212 to provide a guide for uniform spacing of heat shield 202 away from surface 102A.

Ring 504 has outer diameter D_{R}. In at least one implementation, outer diameter D_{R} is greater than outer diameter D_{N1} and diameter D₂. In at least one implementation, portions of ring 504 can be in contact with heat shield 202. In at least one implementation, length L_{N1} is substantially equal to thickness T_{HS} and diameter D_{R} is greater than outer diameter D_{N1} and diameter D₂. In at least one implementation, ring 504 is in contact with surface 202A. Friction between ring 504 and surface 202A and thermal expansion of heat shield 202 can cause sheer forces along the x-direction in the Figure. Shear forces can cause heat shield 202 to bend orthogonally away from surface 202A. In at least one implementation, gap 506 within hole 206A, between nut 216, ring 504 and heat shield 202, provides space for thermal expansion of heat shield 202 and mitigation against adverse impacts of shear forces. In at least one implementation, for mechanical support, ring 504 has thickness T_{R} that is at least 1 mm. In at least one implementation, heat shield 202 can have different configurations such as a disk with multiple holes distributed throughout.

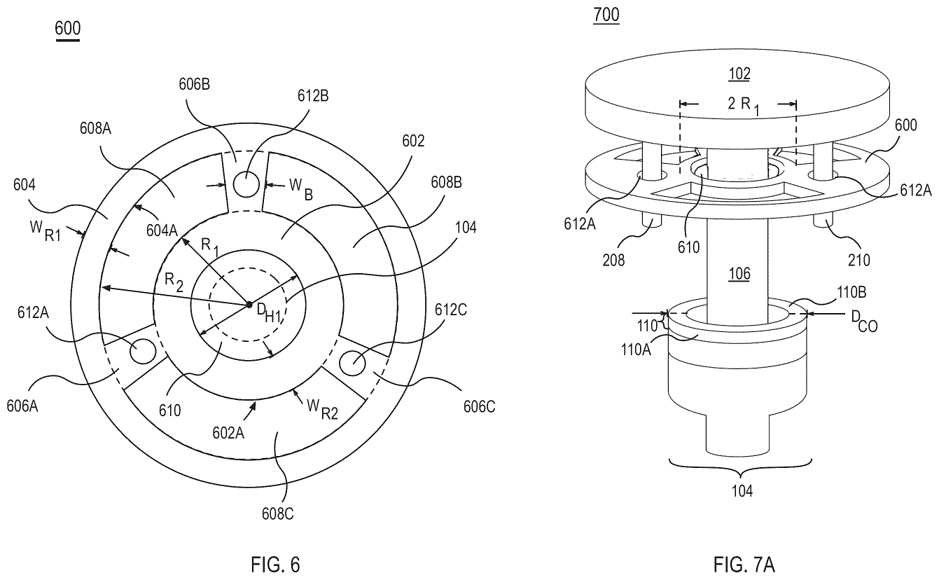

FIG. 6 is a plan-view illustration of a heat shield 600 that is designed to be implemented with electrostatic chuck (such as electrostatic chuck 100 in FIG. 1A), in accordance with at least one implementation. In at least one implementation, heat shield 600 includes ring 602 and ring 604. In at least one implementation, rings 602 and 604 are substantially concentric.

In at least one implementation, rings can be circular or have another shape. In the illustrative implementation, rings 602 and 604 are circular. In at least one implementation, rings 602 and 604 can be annular rings, as illustrated. In at least one implementation, ring 602 has annular width W_{R1}, and ring 604 has annular width W_{R2} (herein width W_{R1} and W_{R2}). Widths W_{R1} and W_{R2} can be the same or be different. In at least one implementation, widths W_{R1} and W_{R2} can vary with application, such as, maximum operating temperature, temperature in a vicinity of clamp and o-ring, etc. In at least one implementation, widths W_{R1} and W_{R2} can also depend on the desired vertical spacing between heat shield 600 and a plate electrode. In at least one implementation, where heat shield 600 is in closer proximity to a plate electrode, W_{R1} and W_{R2} can have narrower widths. In at least one implementation, widths can be narrower because an angle between plate electrode 102 and clamp 110 may be reduced.

Ring 602 has outer radius R₁ and ring 604 has inner radius R₂. In at least one implementation, outer radius R₁ and inner radius R₂ can vary with application. In at least one implementation, heat shield 600 further includes bridge structures 606A, 606B, and 606C. Here, “bridge structure” may generally refer to a structure that connects or couples two structures together. In at least one implementation, bridge structures 606A, 606B, and 606C are directly coupled between rings 602 and 604. In at least one implementation, bridge structures 606A, 606B, and 606C extend from outer radius R₁ and inner radius R₂. In at least one implementation, bridge structures 606A, 606B, and 606C may be connected between outer perimeter 602A of ring 602 and inner perimeter 604A of ring 604. In at least one implementation, bridge structures 606A, 606B, and 606C are designed to be spaced apart equidistant from each other. In at least one implementation, three bridge structures 606A, 606B, and 606C are shown.

In at least one implementation, bridge structures 606A, 606B, and 606C can have different shapes. In at least one implementation, shapes can range from rectangle to wedge-shaped. In at least one implementation, bridge structures 606A, 606B, and 606C are substantially wedge shaped, where a width of the wedge increases with distance away from ring 602.

In at least one implementation, heat shield 600 further includes open spaces or holes collectively between rings 602 and 604, and any two pair of bridge structures. In at least one implementation, shapes and size of the holes depend on shapes of bridge structures 606A-C and on outer radius R₁ and inner radius R₂. In at least one implementation, heat shield 600 includes three holes 608A, 608B, and 608C. In at least one implementation, heat shield 600 includes hole 608A between rings 602 and 604 and bridge structures 606A and 606B. In at least one implementation, heat shield 600 includes hole 608B between rings 602 and 604 and bridge structures 606B and 606C. In at least one implementation, heat shield 600 includes hole 608C between rings 602 and 604 and bridge structures 606A and 606C. In at least one implementation, holes 608A, 608B, and 608C have a plan view surface area that are substantially equal. In at least one implementation, holes 608A, 608B, or 608C individually represent at least 10% of a plan view surface area of heat shield 600. In at least one implementation, holes 608A, 608B, and 608C collectively represent at least 30% of a plan view surface area of heat shield 600. In at least one implementation, plan view surface area of holes 608A, 608B, or 608C can be adjusted by changing lateral width W_{B} of bridge structures 606A, 606B, and 606C. Lateral width W_{B} may be measured along a diameter of hole 608A, 608B, or 608C. In at least one implementation, holes 608A, 608B, or 608C may have an individual plan view surface area that is not substantially equal. In at least one implementation, holes 608A, 608B, and 608C may collectively represent at least 30% of a plan view surface area of heat shield 600.

In at least one implementation, ring 602 includes hole 610 that is designed to be greater than a diameter of column structure 104 (in dashed lines). In at least one implementation, hole 610 is larger than a flange portion of column structure (described in association with FIG. 2A). In at least one implementation, hole 610 is circular, as shown, and may have a diameter D_{H1}. In at least one implementation, diameter D_{H1} is the same or substantially the same as diameter D_{H} of hole 204 in heat shield 202 (FIG. 2A).

In at least one implementation, hole 610 may be circular. In at least one implementation, hole 610 may be another shape, such as square, pentagonal, or hexagonal. In at least one implementation, bridge structures 606A-C can also include one or more holes. In at least one implementation, bridge structure 606A includes hole 612A, bridge structure 606B includes hole 612B, and bridge structure 606C includes hole 612C. Holes 612A-C may have one or more properties of holes 206A-C and are utilized for the same purpose as holes 206A-C (FIG. 2A). In at least one implementation, holes 612A-C, for example, are incorporated to allow retention structures to be inserted through to support heat shield 600. In at least one implementation, holes 612A-C are spaced apart equally from a center of ring 602. In at least one implementation, center of ring 602 is also an axial center of ring 602.

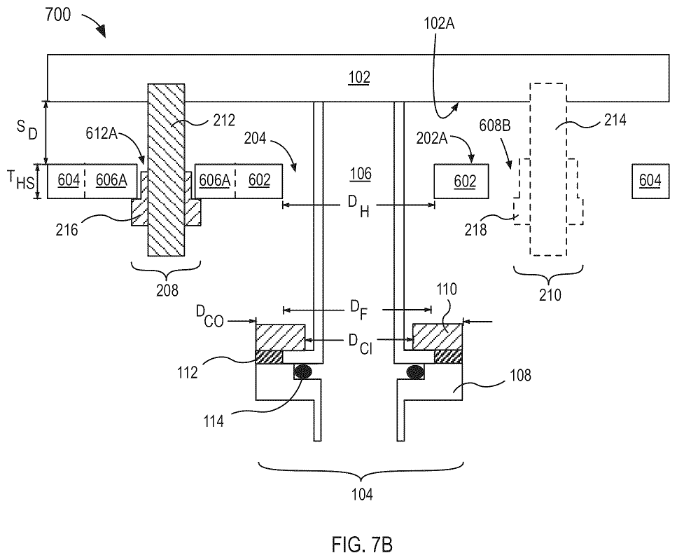

FIG. 7A is an isometric illustration of apparatus 700 which includes an implementation of heat shield 600, in accordance with at least one implementation. In at least one implementation, apparatus 700 includes one or more features of apparatus 200 (FIG. 2A) such as plate electrode 102 and column structure 104. In at least one implementation, heat shield 600 is coupled with plate electrode 102. As shown, stem 106 extends through hole 610. In at least one implementation, apparatus 700 further includes retention structure 208 and retention structure 210 to couple heat shield 600 with plate electrode 102. In at least one implementation, portions of shafts 212 and 214 extend through holes 612A and 612C, respectively, and couple with surface 102A of plate electrode 102.

In at least one implementation, hole 610 may be large enough to cover at least a portion of clamp 110. In at least one implementation, clamp 110 has an outer diameter D_{CO} that is greater than two times the width R₁.

In at least one implementation, clamp 110 includes one or more features of clamp 110 described in association with FIG. 2B. Examples of such features include clamp portions 110A and 110B as indicated by dashed lines. In at least one implementation, portions 110A and 110B may be of substantially equal size.

FIG. 7B is a cross-sectional illustration of apparatus 700 in FIG. 7A through a diameter of plate electrode 102 including bridge structure 606A and retention structure 208, in accordance with at least one implementation. In at least one implementation, holes 612A and 608B are shown in the cross-sectional illustration. In at least one implementation, retention structure 210 is superimposed on the cross-sectional illustration to provide context. In at least one implementation, depending on inner diameter D_{CI} and on outer diameter D_{CO}, some portions of thermal radiation emitted from plate electrode 102 may reach clamp 110.

In at least one implementation, heat shield 600 comprises thickness T_{HS}. Thickness T_{HS} may range between 6 mm and 20 mm to sufficiently provide sufficient heat absorption. In at least one implementation, retention structure 208 further includes nut 216 coupled with shaft 214, and retention structure 208 further includes nut 218 coupled with shaft 214. In at least one implementation, nuts 216 and 218 provide mechanical support for heat shield 202.

In at least one implementation, apparatus 200 or 700 may include multiple heat shields such as heat shield 202 and/or heat shield 600. In at least one implementation, additional heat shields can help to reduce thermal flux as well as thermal gradient between a heat shield closest to a plate electrode, and the clamp.

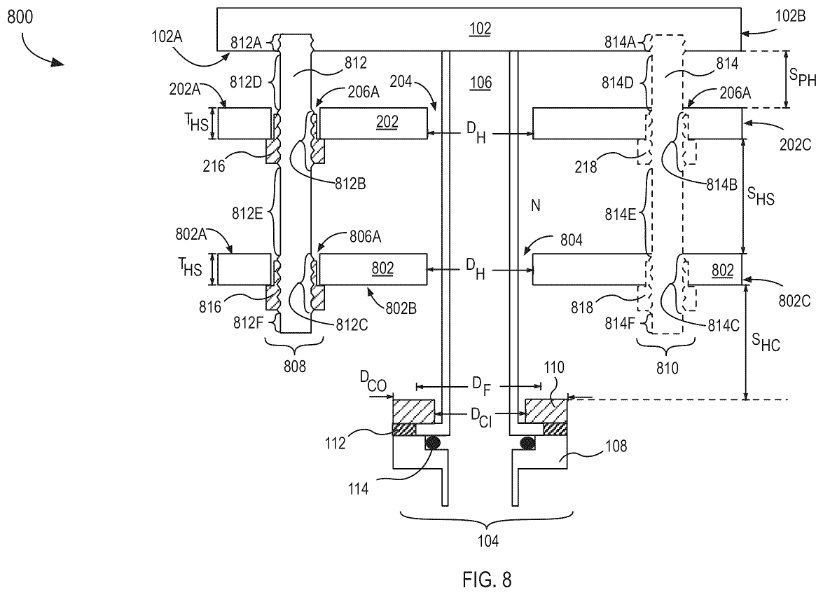

FIG. 8 is a cross-sectional illustration of apparatus 800 that includes two heat shields, in accordance with at least one implementation. The cross-sectional illustration represents a cross section through a diameter of apparatus 800. As such, holes 206A and 806A are shown. In at least one implementation, a second heat shield may be implemented to absorb and deflect residual heat that is deflected and radiated from heat shield 202. In at least one implementation, apparatus 800 includes one or more features of apparatus 200 such as electrostatic chuck 100, column structure 104, and heat shield 202. In at least one implementation, apparatus 800 includes an additional heat shield, such as heat shield 802. In at least one implementation, number of heat shields implemented may be set by thermal gradient to be controlled between plate electrode 102 and clamp 110.

In at least one implementation, heat shield 802 may include one or more features of heat shield 202. In at least one implementation, heat shield 802 is the same or substantially the same as heat shield 202. In at least one implementation, heat shield 802 includes hole 804 at the center of heat shield 802. In at least one implementation, hole 804 can be of a same size as hole 204 or be different. In at least one implementation, hole 804 is below hole 204 and has a same size as hole 204. In at least one implementation, holes 804 and 204 may have axial centers that are vertically aligned. In at least one implementation, column structure 104 extends through holes 804 and 204.

In at least one implementation, holes 204 and 804 are substantially similar in size. In at least one implementation, hole 804 may be small enough to fully cover clamp 110 or large enough to expose portions of clamp 110 at least partially. In at least one implementation, portion of clamp 110 is exposed to surface 102A. In at least one implementation, during operation, thermal radiation emanating from surface 102A can reach clamp 110. In at least one implementation, amount of thermal radiation reaching clamp 110 may partially depend on size of holes 204 and 804 relative to width of stem 106. In at least one implementation, thermal radiation reaching clamp 110 may also depend on spacing S_{PH} between heat shield 202 and plate electrode 102, and to a lesser extent on spacing S_{HS} between heat shield 202 and heat shield 802. Vertical spacing S_{HC} between surface 802B and clamp 110 can also affect total radiation at clamp 110.

In at least one implementation, holes 204 and 804, clamp 110, and stem 106 are circular. In at least one implementation, holes 204 have diameter D_{H}, cylindrical portion of stem 106 has diameter D_{S1}, and clamp 110 has inner diameter D_{CI} and outer diameter D_{CO}. In at least one implementation, diameters D_{H} of holes 204 and 804, relative to diameter D_{S1} of cylindrical portion of stem 106, may partially determine a total amount of thermal radiation entering hole 804. In at least one implementation, a difference between inner diameter D_{CI} and diameter D_{H} may also partially determine a total amount of thermal radiation reaching clamp 110.

In at least one implementation, heat shield 802 further includes a plurality of holes distributed through heat shield 802. In the cross-sectional illustration, hole 806A is shown because other holes may not lie along a diameter of heat shield 802 or 202, in accordance with at least one implementation.

In at least one implementation, heat shield 802 comprises thickness T_{HS2}. In at least one implementation, thickness T_{HS2} may range between 10 mm and 20 mm to provide sufficient absorption of thermal radiation. In at least one implementation, thickness T_{HS2} may not have a same thickness as thickness T_{HS}. In at least one implementation, thickness T_{HS2} is substantially equal to thickness T_{HS}.

In at least one implementation, apparatus 800 further includes retention structure 808 and retention structure 810. In at least one implementation, retention structure 810 is superimposed on the cross-sectional illustration for illustrative purposes only. In at least one implementation, retention structure 810 may not be in the plane of the cross-sectional illustration. In at least one implementation, retention structures 808 and 810 may couple heat shield 202 and heat shield 802 with plate electrode 102. In at least one implementation, retention structure 808 includes shaft 812 and retention structure 810 includes shaft 814. In at least one implementation, portions of shaft 812 extends through holes 206A and 806A and portions of shaft 814 extends through holes in retention structure 810 (not shown). In at least one implementation, threaded portion 812A of shaft 812 couples with surface 102A of plate electrode 102.

In at least one implementation, shafts 812 and 814 include one or more features of shaft 212 and/or 214. In at least one implementation, shaft 812 includes threaded portions 812A, 812B, and 812C, and barrels 812D and 812E. In at least one implementation, shaft 812 can include more threaded portions and barrels to enable addition of more heat shields. In at least one implementation, barrel 812D includes one or more features of barrel 212C. In at least one implementation, barrel 812D extends approximately from surface 202A to surface 102A. In at least one implementation, barrel 812E extends approximately from surface 802A to threaded portion 812B. In at least one implementation, barrels 812D and 812E may not have the same outer diameter. In at least one implementation, barrel 812D may have outer diameter D_{B1} that is greater than diameter D_{B2} of barrel 812E. In at least one implementation, diameter D_{B2} may be at most a diameter of threaded portions 812B and 812C to enable positioning of nut 216.

In at least one implementation, separation distance S_{HS} between heat shield 202 and heat shield 802 may be determined by a number of factors ranging from distance between plate electrode 102 and clamp 110 to the number of heat shields implemented. In at least one implementation, with two heat shields 202 and 802, distance S_{HS} can range between 0.5 cm and 5.5 cm. In at least one implementation, barrel 812E partially defines spacing S_{HS} between heat shield 202 and heat shield 802.

In at least one implementation, retention structure 808 further includes nut 816 coupled with shaft 812. In at least one implementation, nut 816 is utilized as a support for heat shield 802. In at least one implementation, nut 816 includes one or more properties of nut 216 described in association with FIG. 3A. While barrel 812E partially defines spacing S_{HS}, in at least one implementation, nuts 216 and 816 can also set spacing S_{HS}.

In at least one implementation, shaft 814 includes features of shaft 812 such as threaded portions 814A, 814B, and 814C, and barrels 814D and 814E. In at least one implementation, nuts 218 and 818 are coupled with threaded portions 814B and 814C, respectively. In at least one implementation, nuts 218 and 818 provide mechanical support for heat shield 202 and 802, respectively.

In at least one implementation, shafts 812 and 814 further include end portions 812F and 814F, adjacent to threaded portions 812C and 814C, respectively. In at least one implementation, end portions 812F and 814F have a respective length that is advantageously purposed for positioning and threading a nut during assembly of heat shield 802.

In at least one implementation, to provide adequate heat deflection and absorption, heat shields 202 and 802 may be similarly sized as plate electrode 102. In at least one implementation, heat shields 202 and 802 have perimeters 202C and 802C, respectively. In at least one implementation, such as is shown, perimeters 202C and 802C are substantially aligned with perimeter 102B of plate electrode 102.

To facilitate removal and servicing of components, such as o-rings, the shield can be coupled with a surface of the chamber, where the surface is directly under the plate electrode. The inner surface of the shield may not be in thermal contact with the clamp, and the primary and secondary stem pieces to prevent conductive heat transfer. The shield has a height that can be chosen to accommodate a height of the primary stem piece and a thickness of the clamp. The height can be chosen to also provide space to couple the primary stem piece and secondary stem piece during installation. The height of the shield also depends on a separation distance between the shield and the plate electrode. The separation distance can depend on processing conditions and on amount of heat mitigation desired. In some implementations, the separation distance can be at least 25% of a length of the primary stem piece.

In other implementations, a cap can be coupled with the shield. The cap can be coupled with a top portion of a cylindrical shield. For practical considerations, the cap can have an opening that is at least a diameter of the primary stem piece. The cap can provide additional protection against radiative heat transfer to the clamp by reducing a solid angle subtended between the plate electrode and the clamp.

In other implementations, heat radiated from the plate electrode can be at least partially prevented from reaching portions of the primary stem piece and clamp by insertion of a heat shield. The heat shield can be solid metallic, perforated, or comprise large openings. The structure of the heat shield can depend on processing conditions such as temperature, process duration, and on processing chemistry utilized, etc.

The heat shield can be coupled with a top surface of the shield. The heat shield can be a disk that is larger than the shield. The heat shield can rest on the shield and can be bolted for mechanical stability. The heat shield can have an opening that is at least a diameter of the primary stem piece. Additionally, the heat shield can have multiple openings to accommodate components (for example, pusher pins) that are coupled directly under the plate electrode. Pusher pins are utilized in an electrostatic chuck to enable lowering and raising of substrates from a surface of plate electrode before and after processing. In at least one implementation, a heat shield is provided to accommodate pusher pins.

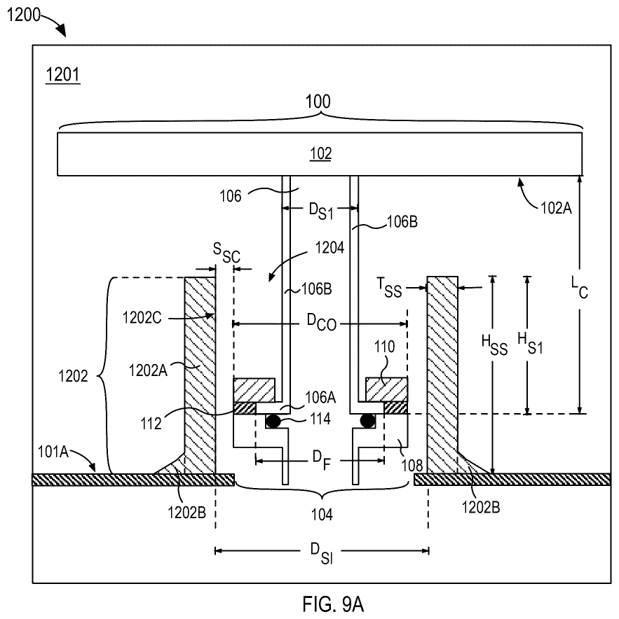

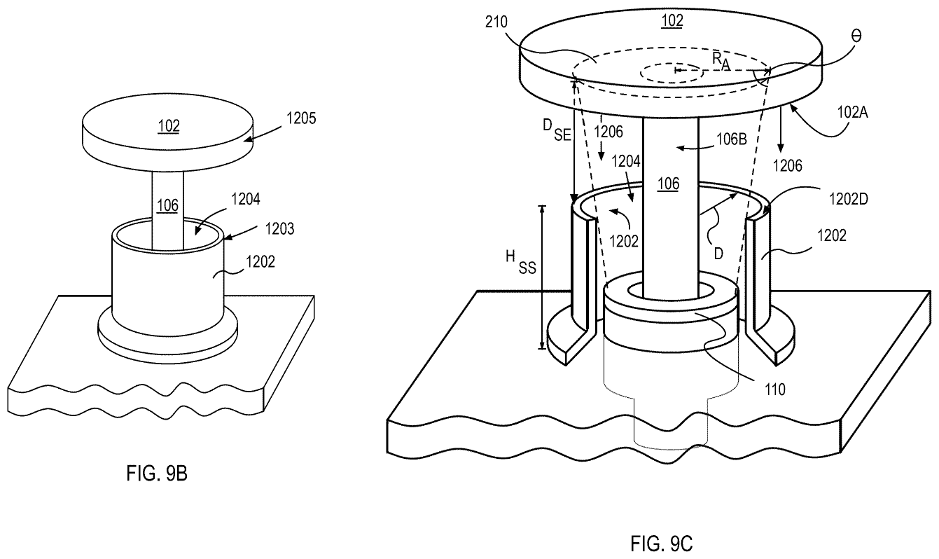

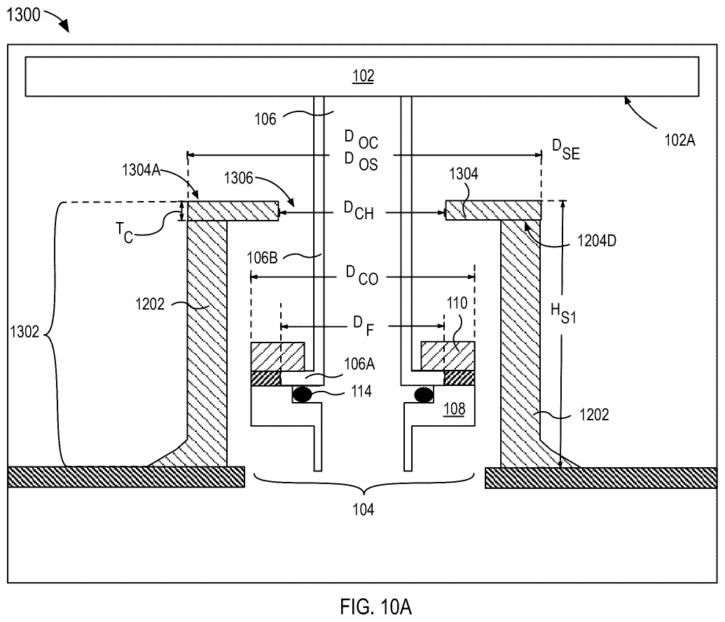

FIG. 9A is a cross-sectional illustration of apparatus 1200 that includes chamber 1201 with electrostatic chuck 100 (illustrated in FIG. 1A) and shield 1202, in accordance with at least one implementation. In at least one implementation, stem shield 1202 can be a hollow cylindrical structure. In at least one implementation of FIG. 9A, shield 1202 surrounds and extends circumferentially around at least a portion of stem 106 and a portion of stem 108. In at least one implementation, shield 1202 also surrounds and extends circumferentially around at least a portion of clamp 110 and insulator ring 112. In at least one implementation, shield 1202 can be designed to block thermal radiation from reaching clamp 110 at least partially.

Here, “hollow cylindrical structure” can generally refer to a cylinder with a wall that has a thickness that is lesser than diameter of the cylinder. In at least one implementation, shield 1202 comprises wall thickness T_{SS}. In at least one implementation, thickness T_{SS} can range from 10 mm to 20 mm to provide a desired degree of heat absorption. In an implementation, shield 1202 comprises aluminum, alumina, or aluminum nitride.

In at least one implementation, such as is shown in FIG. 9A, shield 1202 can include cylindrical portion 1202A and base ring (herein ring 1202B) extending circumferentially around a base (or a lowermost portion) of cylindrical portion 1202A. In at least one implementation, cylindrical portion 1202A can have an opening, such as opening 1204. In at least one implementation, ring 1202B is below clamp 110, e.g., situated between the lowermost end/portion of the cylindrical portion 1202A and the clamp 110.

In at least one implementation, shield 1202 can be coupled with chamber 1201. In at least one implementation, shield 1202 is on surface 101A of chamber 1201. In at least one implementation, ring 1202B can extend laterally on surface 101A to provide stability. In at least one implementation, ring 1202B can be coupled to surface 101A, for example bolted or otherwise connected to surface 101A. In at least one implementation, ring 1202B can be unsecured to surface 101A to provide for thermal expansion and contraction of shield 1202.

In at least one implementation, shield 1202 may not be in mechanical contact with the column structure 104 or clamp 110. In at least one implementation, shield 1202 has an inner diameter D_{SI} (herein diameter D_{SI}). In at least one implementation, diameter D_{SI} can be greater than outer diameter D_{CO} of clamp 110. In at least one implementation, separation S_{SC} between shield 1202 and outer diameter D_{CO} of clamp 110 can provide isolation from thermal conduction. In at least one implementation, S_{SC} is at least 1 mm. In at least one implementation, during operation, heat absorbed by shield 1202 can be designed to be transferred to surface 101A. In at least one implementation, surface 101A can be a thermal conductor. In at least one implementation, column structure 104 and clamp 110 can also absorb heat through radiative heat transfer in addition to conductive heat transfer. In at least one implementation, radiative heat transfer can occur from sidewall surface 1202C to column structure 104 and clamp 110. In at least one implementation, radiative heat from sidewall surface 1202C can be significantly less than radiative heat directly from surface 102A.

In at least one implementation, stem 106 includes a cylindrical body with sidewall 106B and a base flange 106A attached to the cylindrical body. In at least one implementation, base flange 106A has diameter D_{F}. Diameter D_{SI} greater than diameter D_{F} by at least 1 mm. In at least one implementation, diameter D_{SI} greater than diameter D_{F} by at least 5 mm.

In at least one implementation, shield 1202 has height H_{SS}, measured relative to surface 101A. In at least one implementation, a first portion of shield 1202 extends below clamp 110 and o-ring 114 and a second portion extends height H_{S1} above a base of stem 106. In at least one implementation, the first portion of shield 1202 extends longitudinally beyond a lowermost end or surface of the clamp 110. In at least one implementation, height H_{S1} can be at least 30% of length L_{C} (axially along y-direction) of stem 106. In at least one implementation, height H_{S1} can be at least 30% but less than 50% of length L_{C} (along y-direction) of stem 106. In at least one implementation, height H_{S1} can be at least 50% of length L_{C} (along y-direction) of stem 106.

FIG. 9B is an isometric illustration of the apparatus 1200 in FIG. 9A, in accordance with at least one implementation. In at least one implementation, shield 1202 is a cylinder. In at least one implementation, plate electrode 102 can have a circular shape to provide uniform process conditions for a circular substrate. In at least one implementation, column structure 104, clamp 110, insulator ring 112, stems 106 and 108, and opening 1204 are substantially circular.

In at least one implementation, shield 1202 has substantially smaller perimeter 1203 compared to perimeter 1205 of plate electrode 102. In at least one implementation, a smaller perimeter can help to limit thermal radiation flux on clamp 110. In at least one implementation, thermal radiation from plate electrode 102 can be directed towards surface 101A. In at least one implementation, shield 1202 has perimeter 1203. Perimeter 1203 can also be chosen to prevent mechanical interference with movable components of plate electrode 102 such as pusher pins (not shown).

FIG. 9C is the isometric illustration in FIG. 9B where portions of shield 1202 are cut out to reveal stem 106 and clamp 110, in accordance with at least one implementation. In at least one implementation, geometrical effects of shield 1202 and its impact on total thermal radiation flux at clamp 110 are shown. In at least one implementation, thermal radiation (indicated by arrows 1206) that emanates from surface 102A can reach clamp 110. In at least one implementation, amount of thermal radiation reaching clamp 110 can depend on several factors. In at least one implementation, factors include size of opening 1204 relative to sidewall 106B and height H_{SS} of shield 1202 relative to clamp 110.

In at least one implementation, surface 1202D of shield 1202 extends distance D_{SE} from surface 102A. In at least one implementation, distance D_{SE} and distance D_{S} between sidewall 106B and sidewall surface 1202C can partially determine heat flux at clamp 110. In at least one implementation, by changing distances D_{SE} and D_{S}, an angle theta, subtended between surface 102A and clamp 110 can be tuned. In at least one implementation, angle theta can directly corelate to a size of annular portion 1210 of surface 102A. In at least one implementation, annular portion 1210 has radius R_{A} relative to an axial center of plate electrode 102. In at least one implementation, radius R_{A} can change with changes in distance D_{SE} and/or distance D_{S}. In at least one implementation, thermal radiation (denoted by arrows 1206) can be tuned by changing an effective area of annular portion 1210.

In at least one implementation, heat flux can be reduced by reducing distance S_{SE}. In at least one implementation, reducing distance D_{S} can help to reduce heat flux. In at least one implementation, reducing distance S_{SE} and distance D_{S} together can collectively reduce heat flux by an even greater amount.

In at least one implementation, shield 1202 can include modifications that advantageously provide for further reduction in heat flux at clamp 110. In at least one implementation, modifications include additional adapters coupled with shield 1202.

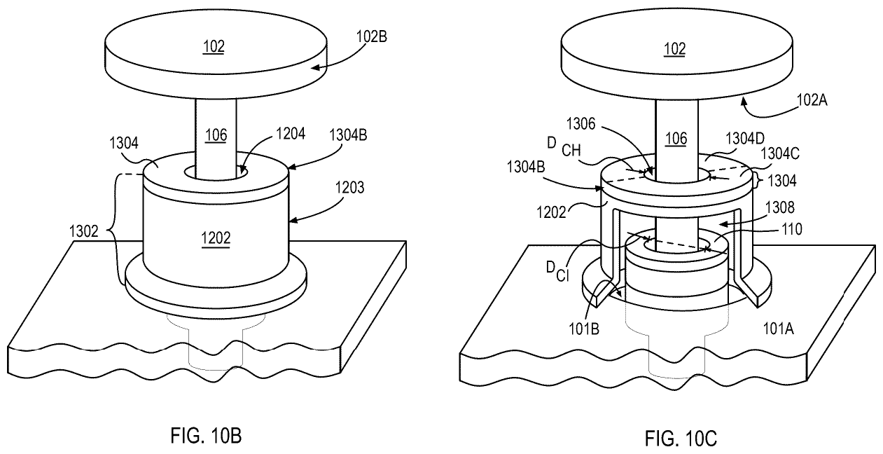

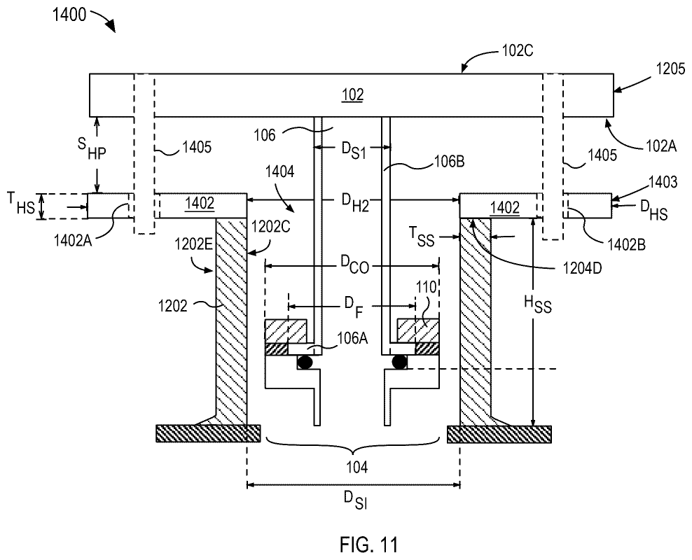

FIG. 10A is a cross-sectional illustration of apparatus 1300 that includes plate electrode 102, column structure 104, and cap shield 1302, in at least one implementation. In at least one implementation, cap shield 1302 includes shield 1202 and cap 1304 positioned on shield 1202. In at least one implementation, shield 1202 includes one or more features of shield 1202 described in association with FIG. 9A.

Here, “cap” can generally refer to a disk structure that is designed to block thermal radiation at least partially. Referring again to FIG. 10A, in at least one implementation, cap 1304 can be flush with shield 1202. In at least one implementation, cap 1304 has outer diameter D_{OC} that is the same or substantially the same as an outer diameter D_{OS} of shield 1202. In at least one implementation, cap 1304 is in thermal contact with surface 1202D of shield 1202. In at least one implementation, surface 1202D can provide sufficient mechanical stability for cap 1304.

In at least one implementation, cap 1304 can include a same material as the material of shield 1202. In at least one implementation, cap 1304 can include a different material from a material of shield 1202. In at least one implementation, shield 1202 should be thermally conductive and chemically inert. In at least one implementation, materials that are thermally conductive and chemically inert include aluminum and aluminum nitride. In at least one implementation, cap 1304 can comprise aluminum or alumina. In at least one implementation, cap 1304 can be less conductive than shield 1202 and includes alumina (Al₂O₃). In at least one implementation, shield 1202 includes aluminum and cap includes alumina (Al₂O₃). In at least one implementation, shield 1202 includes aluminum nitride and cap includes alumina (Al₂O₃). Cap 1304 has thickness T_{C} that is designed to adequately provide thermal conduction. In at least one implementation, thickness T_{C} can be tuned depending on materials utilized and on a specific process application. The specific process application, for example, can set a range operational temperature of plate electrode 102. In at least one implementation, heat radiated from plate electrode 102 can be proportional to the operational temperature range of plate electrode 102. In at least one implementation, surface 1304A can be coated to reflect thermal radiation from surfaces of cap shield 1302 towards chamber 1201 and plate electrode 102.

In at least one implementation, cap 1304 also includes opening 1306. Size of opening 1306 can be dependent on relative sizes of clamp 110 and stem 106 for practical considerations (such as installation of cap shield 1302). In at least one implementation, stem 106 includes a cylindrical body with sidewall 106B and base flange 106A attached to sidewall 106B. Base flange 106A has diameter D_{F}. In at least one implementation of cap shield 1302, opening 1306 has diameter D_{CH}, that can be greater than diameter D_{F}. In at least one implementation, diameter D_{CH} can be greater than diameter D_{F} but less than outer diameter D_{CO}. In at least one implementation, diameter D_{CH} can be greater than outer diameter D_{CO}.

In at least one implementation, cap 1304 has thickness T_{C}. Cap 1304 can reduce distance D_{SE} between surface 1204D and surface 102A. In at least one implementation, cap shield has height H_{S1}, where height H_{S1} is measured relative to surface 101A. In at least one implementation, distance D_{SE} is between 25 mm and 75 mm and height H_{S1} is between 12 mm and 75 mm.

FIG. 10B is an isometric illustration of the structure in FIG. 10A, in accordance with at least one implementation. In at least one implementation, shield 1202 is a cylinder. In at least one implementation, plate electrode 102 can have a circular shape to provide uniform process conditions for a circular substrate. In at least one implementation, column structure 104, clamp 110, insulator ring 112, stems 106 and 108, and opening 1204 are substantially circular. In the illustrative implementation, opening 1306 is also circular. In at least one implementation, size of opening 1306 can limit total radiated heat flux towards lower portion of stem 106 that is below cap 1304 and clamp 110.

In at least one implementation, cap shield 1302 has a substantially smaller perimeter 1304B compared to perimeter 102B of plate electrode 102. In at least one implementation, a smaller perimeter 1304B can help to limit thermal flux at clamp 110.

In at least one implementation, cap 1304 is circular. Perimeter 1304B of cap 1304 can be substantially aligned with perimeter 1203. In at least one implementation, cap 1304 can be mechanically stable as one end of cap 1304 can be peripherally supported by a substantially thick wall that defines perimeter 1203. In at least one implementation, perimeter 1304B can be chosen to prevent mechanical interference with movable components of plate electrode 102 such as pusher pins.

FIG. 10C is an isometric illustration of the structure in FIG. 10A, in accordance with at least one implementation. In at least one implementation, cut out portion 1308 in shield 1202 illustrates a line of sight for thermal flux reaching clamp 110.

In at least one implementation, where opening 1306 exposes clamp 110, some thermal flux can reach clamp 110. In at least one implementation, thermal flux at clamp 110 in the presence of cap 1304 can be less than with an absence of cap 1304 (such as is shown in FIG. 9C).

In at least one implementation, opening 1306 may not expose clamp 110. For example, diameter D_{CH} is less than inner diameter D_{CI}. In at least one implementation, thermal flux radiated from surface 102A can be limited to a portion that can enter opening 1306. In at least one implementation, thermal flux can be incident on flange portions of stem 106.

In at least one implementation, cap 1304 can comprise two separate portions, such as portion 1304C and portion 1304D illustrated by dashed lines. In at least one implementation, portions 1304D and 1304D can reduce a size of opening 1306 compared to a size of diameter D_{CI} of clamp 110. In at least one implementation, opening 1204 can have a size that is at least greater than a size of flange portions of stem 106 (as illustrated in FIG. 10A). In at least one implementation, portions 1304C and 1304D can be coupled with shield 1202 with screws or bolts (not shown).

In at least one implementation, surface 101A includes opening 101B. In other implementations, portions of cap 1304 can be larger and extend outward away from perimeter 1304B. In at least one implementation, cap 1304 can be replaced with a heat shield that can extend parallel to surface 102A as described below.

FIG. 11 is a cross-sectional illustration of an apparatus 1400 that includes heat shield 1402, in accordance with at least one implementation. In at least one implementation, apparatus 1400 includes many features of apparatus 1200 including plate electrode 102, shield 1202 and column structure 104. In at least one implementation, heat shield 1402 can be disposed between plate electrode 102 and shield 1202. In at least one implementation, heat shield 1402 can be coupled with shield 1202. In at least one implementation, a portion of heat shield 1402 is on shield 1202.

In at least one implementation, heat shield 1402 comprises a disk. In some such implementations, heat shield 1402 has diameter D_{HS}. In at least one implementation, heat shield 1402 extends laterally parallel to plate electrode 102. In at least one implementation, heat shield 1402 can be as wide as plate electrode 102, as shown. In at least one implementation, heat shield 1402 can be used to absorb or deflect a significant portion of thermal radiation from surface 102A.

In at least one implementation, heat shield 1402 includes opening 1404 with an opening diameter D_{H2}. In at least one implementation, amount of radiated thermal radiation absorbed or reflected by heat shield 1402 can depend on diameter D_{H2}. In at least one implementation, diameter D_{H2} is substantially the same size as inner diameter D_{SI} of shield 1202.

In at least one implementation, diameter D_{H2} is smaller than inner diameter D_{SI}. In at least one implementation, heat shield is not aligned with sidewall surface 1202C. In at least one implementation, where diameter D_{H2} is smaller than inner diameter D_{SI,} diameter D_{H2} can be at least larger than outer diameter D_{CO} for assembly of heat shield onto shield 1202. In at least one implementation, clamp 110 can comprise separate segments or portions that can be combined to form clamp 110. In at least one implementation, diameter D_{H2} can be smaller than outer diameter D_{CO}. In at least one implementation, diameter D_{H2} is greater than diameter D_{F} of base flange 106A of stem 106. In at least one implementation, diameter D_{H2} is greater than diameter D_{F} by at least 1 mm.

In at least one implementation, heat shield 1402 can be supported by shield 1202 on surface 1202D, as shown. In at least one implementation, heat shield 1402 can be placed on shield 1202 to provide flexibility during thermal expansion and contraction of heat shield 1402 and shield 1202. In at least one implementation, heat shield 1402 can be fastened on to surface 1202D for mechanical stability by screws or bolts. In at least one implementation, shield has thickness T_{SS} that can be sufficient to support heat shield 1402.

In at least one implementation, a desired separation S_{HP}, between heat shield 1402 and surface 102A can depend on operating conditions of plate electrode 102. In at least one implementation, different operating conditions can heat plate electrode 102 to different temperatures. In at least one implementation, different temperatures of plate electrode 102 can radiate varying levels of thermal radiation. In at least one implementation, height H_{SS} of shield 1202 can be tuned to provide suitable separation S_{HP}. In at least one implementation, height H_{SS} is measured from surface 101A. In at least one implementation, separation S_{HP} can be 20 mm or more.

In at least one implementation, heat shield 1402 has thickness T_{HS} that is sufficient to absorb thermal radiation. In at least one implementation, heat shield 1402 has thickness T_{HS} that is in the range of 1 mm to 6 mm. In at least one implementation, thickness T_{HS} can be substantially uniform across diameter D_{HS}.

In at least one implementation, heat shield 1402 can extend beyond sidewall 1202E. In at least one implementation, heat shield 1402 can extend beyond sidewall 1202E and be confined within perimeter 1205 of plate electrode 102. In at least one implementation, heat shield 1402 extends to perimeter 1205 of plate electrode 102. In at least one implementation, heat shield 1402 has a perimeter 1403 that is substantially aligned with perimeter 1205.

In at least one implementation, where heat shield 1402 can extend beyond shield 1202, as shown, heat shield 1402 can further include one or more openings, such as openings 1402A and 1402B, in addition to opening 1404. In at least one implementation, openings 1402A and 1402B can lie along diameter D_{HS}. In at least one implementation, openings 1402A and 1402B are shown in the same cross-sectional plane. In at least one implementation, openings 1402A and 1402B are not positioned along diameter D_{HS}. In at least one implementation, additional openings, such as openings 1402A and 1402B, can be distributed throughout heat shield 1402.

In at least one implementation, such openings can be used to facilitate components that are coupled with plate electrode 102 for functionality. In at least one implementation, such components include pusher pins 1405 (within dashed lines). In at least one implementation, pusher pins 1405 can be utilized in lowering and raising substrates from surface 102C of plate electrode 102. In at least one implementation, the number of openings can be at least three. In at least one implementation, opening 1402A and 1402B, can be spaced apart uniformly throughout heat shield 1402. In at least one implementation, opening 1402A and 1402B are at approximately same radii from a center of heat shield 1402. In at least one implementation, openings 1402A and 1402B have a diameter of at least 3 mm.

In at least one implementation, heat shield 1402 can also extend within shield 1202. In at least one implementation, opening 1404 can be at least greater than diameter D_{S1} of base flange 106A. In at least one implementation, opening 1404 can be at least greater than diameter D_{CO} of clamp 110.

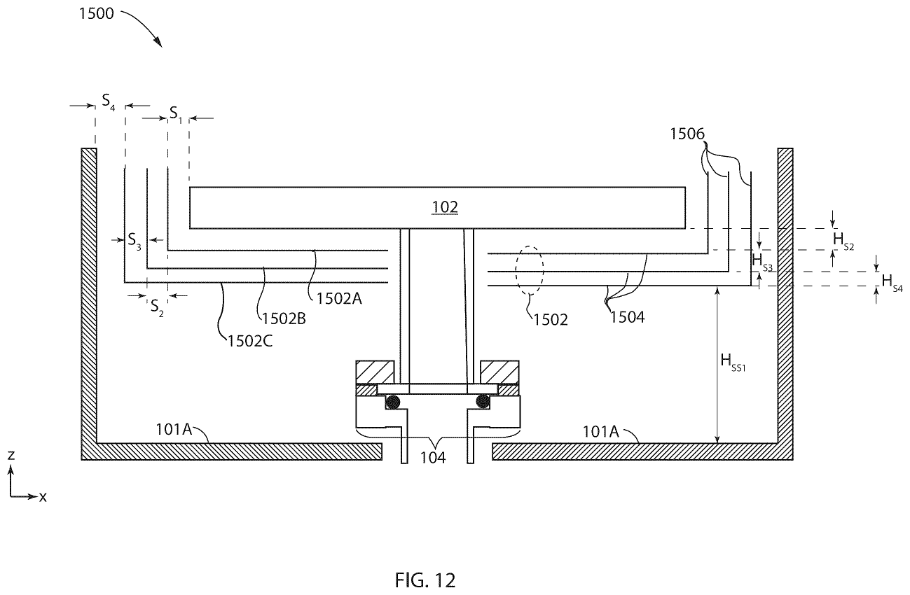

FIG. 12 is a cross-sectional illustration of apparatus 1500 that includes multilayer heat shield structure 1502, in accordance with at least one implementation. In at least one implementation, apparatus 1500 includes many features of apparatus 1200, including plate electrode 102, column structure 104. In at least one implementation, apparatus 1500 includes multilayer heat shield structure 1502 between plate electrode 102 and surface 101A, where surface 101A is a surface of a vacuum chamber (e.g., chamber 101). In at least one implementation, multilayer heat shield structure 1502 comprises heat shield shells 1502A, 1502B, and 1502C.

In at least one implementation, heat shield shells 1502A, 1502B, and 1502C are cylindrical structures having respectively decreasing diameters, and are concentrically nested and centered about column structure 104. In at least one implementation, heat shield shells 1502A, 1502B, and 1502C each comprise horizontal surface 1504 (e.g., extending in the x-direction) and vertical surface 1506 (e.g., extending in the z-direction). In at least one implementation, horizontal surface 1504 has a large view factor facing the bottom surface of plate electrode and column structure 104, as well as surface 101A of the vacuum chamber. In at least one implementation, vertical surface 1506 has a large view factor facing edges of plate electrode 102 and vertical walls of the vacuum chamber (e.g., vertical portions of surface 101A). In at least one implementation, horizontal surface 1504 may absorb and re-radiate heat in substantially vertical (z-axis) directions, whereas vertical surface 1506 may absorb and re-radiate heat in substantially horizontal (x-axis) directions. In at least one implementation, a stacked configuration of heat shield shells 1502A-1502C may enable a finer tuning of temperature profiles within plate electrode 102 and column structure 104 than is achievable with a single layer heat shield structure such as described above.

In at least one implementation, heat shield shells 1502A-1502C provide a gradual stepped reduction in radiative heat transfer between plate electrode 102 and surface 101A or components within column structure 104. In at least one implementation, heat shield shells 1502A, 1502B and 1502C are thermally coupled to each other and to plate electrode 102 and to surface 101A, at least in part by radiative heat transfer. In at least one implementation, heat shield shell 1502A, 1502B and 1502C are in mechanical contact with one another, and are thermally coupled to one another and to plate electrode 102 and to surface 101A, at least in part by conductive heat transfer. In at least one implementation, radiative heat transfer is a primary mechanism of thermal coupling between heat shield shells 1502A-1502C and surroundings (e.g., surface 101A and plate electrode 102).

Unregulated thermal power losses from plate electrode 102 may incur non-uniformities in temperature profiles across plate electrode 102, resulting in thermal stresses that may damage portions of plate electrode 102. Provision of nested heat shield shells 1502A-1502C, for example, can significantly mitigate unregulated thermal power losses from plate electrode 102 by direct exposure to surface 101A. During steady-state operation, plate electrode 102 may be in thermal equilibrium with multilayer heat shield 1502. In at least one implementation, heat shield shell 1502A, being closest to plate electrode 102, has a steady-state temperature that is lower than the temperature of the periphery of plate electrode 102. Heat shield shell 1502B may be at a lower temperature than heat shield shell 1502A, whereas heat shield shell 1502C may have a lower temperature than heat shield shell 1502B. Heat shield shell 1502C is thermally coupled to surface 101A and other surrounding elements within the vacuum chamber. With a temperature that may be significantly lower than plate electrode 102, radiative heat transfer to surface 101A and portions of column structure 104 are reduced. In particular, column structure 104 is effectively shielded from plate electrode 102 by multilayer heat shield 1502. Components within column structure 104 are protected from excessive heat exposure by multilayer heat shield 1502. In at least one implementation, surface 101A provides a heat sinking function as it may be actively cooled, for example by cooling water circulation on the outer surfaces of the vacuum chamber. By providing controlled incremental reduction of temperature, multilayer heat shield 1502 may provide enhanced and tunable heat shielding of plate electrode 102 from surface 101A.

For example, in at least one implementation, thermal power losses from plate electrode 102 may be regulated by adjustment of separation distances S₁ and H_{S2} between plate electrode 102 and heat shield shell 1502A to reduce temperature gradients within plate electrode 102. In at least one implementation, thermal power losses from plate electrode 102 may be regulated by adjustment of separation distances S₂ and H_{S3} between heat shield shells 1502A and 1502B to reduce temperature gradients within plate electrode 102. In at least one implementation, thermal power losses from plate electrode 102 may be regulated by adjustment of separation distances S₃ and H_{S4} between heat shield shells 1502B and 1502C. In at least one implementation, thermal power losses from plate electrode 102 may be regulated by adjustment of separation distances S₄ and H_{SS1} between heat shield shell 1502C and surface 101A.

In at least one implementation, radiative heat transfer from plate electrode 102 may be further tuned by choice of thickness and materials for multilayer heat shield structure 1502. In at least one implementation, some ceramic materials (e.g., aluminum nitride) may have similar thermal conductivities as many metals but with a higher heat capacity. As such, retaining more heat and having a slower temperature increase while absorbing greater amounts of heat than a metal. These properties may be advantageous in a dynamic thermal environment presented by the processing conditions. Ceramic materials are refractory, withstanding higher temperatures than metals, and may retain their emissivity as they do not develop a surface patina over time as metals may do, rendering them less emissive over time.

In the following paragraphs, additional examples are provided in view of the above-described implementations. Here, one or more features of an example, in isolation or in combination, can be combined with one or more features of one or more other examples to form further examples also falling within the scope of the disclosure. As such, one implementation can be combined with one or more other implementation without changing the scope of disclosure.

Example 1 is an apparatus comprising: an electrostatic chuck comprising: a plate electrode; and a column structure coupled with the plate electrode; a disk coupled with the electrostatic chuck, the disk comprising: a first hole which is substantially in a center of the disk; and a second hole and a third hole distributed through the disk, wherein a portion of the column structure extends through the first hole; and a first retention structure and a second retention structure, wherein the first retention structure comprises: a first shaft and a first nut coupled with the first shaft and the disk; and a second nut coupled with a second shaft and the disk, wherein the first shaft extends through the second hole, wherein the second shaft extends through the third hole, and wherein the first shaft and the second shaft coupled with a surface of the plate electrode.

Example 2 is an apparatus according to any examples herein, particularly example 1, wherein the disk has a thickness between 6 cm and 1.5 cm.

Example 3 is an apparatus according to any examples herein, particularly example 1, wherein the second hole and the third hole have a length between 12 mm and 50 mm.

Example 4 is an apparatus according to any examples herein, particularly example 3, further comprises a fourth hole, wherein the fourth hole has a length between 12 mm and 50 mm.

Example 5 is an apparatus according to any examples herein, particularly example 4, wherein the second hole, the third hole, and the fourth hole are uniformly spaced apart from each other and are at an approximately same radius from the center of the disk.

Example 6 is an apparatus according to any examples herein, particularly example 1, wherein the column structure further comprises: a first stem connected to the plate electrode; a second stem coupled with the first stem; a ring directly between the first stem and the second stem; and a clamp coupled with the first stem and the second stem.

Example 7 is an apparatus according to any examples herein, particularly example 6, wherein the first hole has a first diameter, wherein the clamp has a second inner diameter, and wherein the first diameter is greater than the second inner diameter by at least 1 mm.

Example 8 is an apparatus according to any examples herein, particularly example 7, wherein the first stem has a third diameter, and wherein the second inner diameter is greater than the third diameter by at least 1 mm.

Example 9 is an apparatus according to any examples herein, particularly example 1, wherein the first shaft and the second shaft comprise: a hollow core with a variable outer diameter; a first threaded portion at a first end; a second threaded portion; a barrel between the first threaded portion and the second threaded portion.

Example 10 is an apparatus according to any examples herein, particularly example 9, wherein the hollow core extends a length of the first shaft or the second shaft.

Example 11 is an apparatus according to any examples herein, particularly example 10, wherein the first shaft and the second shaft are not in contact with the disk.

Example 12 is an apparatus according to any examples herein, particularly example 10, wherein the barrel has a length of at least 3 mm.

Example 13 is an apparatus according to any examples herein, particularly example 9, wherein the second threaded portion is adjacent to the disk.

Example 14 is an apparatus according to any examples herein, particularly example 12, wherein the first nut and the second nut comprise a first portion and a second portion, wherein the first portion comprises a first outer diameter, and wherein the second portion comprises a second outer diameter.

Example 15 is an apparatus according to any examples herein, particularly example 14, wherein the second hole and the third hole comprise a length that is greater than the second outer diameter by at least 2 mm.

Example 16 is an apparatus according to any examples herein, particularly example 2, wherein the second hole and the third hole comprise a first tapered sidewall and a second tapered sidewall, wherein the first tapered sidewall extends from a first surface to substantially half the thickness of the disk, and wherein the second tapered sidewall extends from half the thickness of the disk to a second surface, and wherein the first tapered sidewall and the second tapered sidewall are oppositely tapered.

Example 17 is an apparatus according to any examples herein, particularly example 1, wherein first and second portions of the first nut and the second nut extend through the disk.

Example 18 is an apparatus according to any examples herein, particularly example 1, wherein the first shaft the second shaft comprise a first material, and wherein the first nut the second nut comprise a second material.

Example 19 is an apparatus according to any examples herein, particularly example 9, wherein the first threaded portion extends partially into the plate electrode through a bottom surface of the plate electrode.

Example 20 is an apparatus according to any examples herein, particularly example 9, wherein the first shaft comprises a first hollow core which extends along a first length of the first shaft, and wherein the second shaft comprises a second hollow core that extends along a second length of the second shaft.

Example 21 is an apparatus according to any examples herein, particularly example 9, wherein the first shaft and the second shaft further comprise a ring between the second threaded portion and the barrel.

Example 22 is an apparatus according to any examples herein, particularly example 21, wherein portions of the ring are in contact with the disk.

Example 23 is an apparatus according to any examples herein, particularly example 22, wherein the ring comprises a third outer diameter that is greater than a length of the first hole and the second hole.

Example 24 is an apparatus according to any examples herein, particularly example 1, wherein the disk does not extend outside a perimeter of the plate electrode.

Example 25 is an apparatus according to any examples herein, particularly example 1, wherein the disk comprises a first perimeter, wherein the plate electrode comprises a second perimeter, and wherein the first perimeter is substantially aligned with the second perimeter.

Example 26: An apparatus comprising: an electrostatic chuck comprising a plate electrode and a column structure coupled with the plate electrode; a disk coupled with the electrostatic chuck, the disk comprising: a first ring and a second ring, wherein the column structure extends through the first ring; and a first bridge structure and a second bridge structure coupled between the first ring and the second ring, wherein the first bridge structure comprises a first hole and the second bridge structure comprises a second hole; and a first retention structure and a second retention structure, wherein the first retention structure extends through the first hole, wherein the second retention structure extends through the second hole, wherein the first retention structure comprises a first shaft and a first nut coupled with the first shaft and the disk, wherein the second retention structure comprises a second shaft and a second nut coupled with the second shaft and the disk, and wherein the first shaft and the second shaft are coupled with a surface of the plate electrode.

Example 27 is an apparatus according to any examples herein, particularly example 26, wherein the first hole and the second hole are spaced apart equally from a center of the first ring.

Example 28 is an apparatus according to any examples herein, particularly example 27, wherein the disk further comprises a third hole between the first ring, the second ring, the first bridge structure, and the second bridge structure.

Example 29 is an apparatus according to any examples herein, particularly example 28, wherein the third hole represents at least 10% of a surface area of the disk, and wherein the first hole, the second hole and the third hole collectively represent at least 30% of the surface area of the disk.

Example 30 is an apparatus according to any examples herein, particularly example 26, wherein the first ring comprises a first lateral thickness, and wherein the second ring comprises a second lateral thickness.

Example 31 is an apparatus according to any examples herein, particularly example 26, wherein the first ring comprises a circular hole.

Example 32 is an apparatus according to any examples herein, particularly example 26, wherein the first ring comprises a hexagonal shaped hole.

Example 1a : An apparatus comprising: an electrostatic chuck comprising: a plate electrode; and a column structure coupled to the plate electrode; a clamp coupled to a base of the column structure; and a shield that extends circumferentially around at least a portion of the clamp and the column structure.

Example 2a is an apparatus according to any examples herein, particularly example 1a, wherein the shield has a cylindrical structure and wherein the cylindrical structure extends longitudinally beyond an end of the clamp.

Example 3a is an apparatus according to any examples herein, particularly example 2a, wherein the shield further comprises a base ring around a lowermost portion of the cylindrical structure.

Example 4a is an apparatus according to any examples herein, particularly example 3a, wherein the electrostatic chuck is situated within a chamber, and wherein the base ring is coupled with a surface of the chamber.

Example 5a is an apparatus according to any examples herein, particularly example 1a, wherein the shield extends axially along 30%-50% of a length of the column structure.

Example 6a is an apparatus according to any examples herein, particularly example 1a, wherein the shield extends axially along at least 50% of a length of the column structure.

Example 7a is an apparatus according to any examples herein, particularly example 2a, wherein the cylindrical structure comprises an inner diameter and the column structure comprises a first diameter, and wherein the inner diameter of the cylindrical structure is greater than the first diameter of the column structure by at least 1 mm.

Example 8a is an apparatus according to any examples herein, particularly example 7a, wherein the clamp comprises an inner diameter, and wherein the inner diameter of the clamp is greater than the first diameter of the column structure by at least 3 mm.

Example 9a is an apparatus according to any examples herein, particularly example 7a, wherein the clamp comprises an outer diameter that is less than the inner diameter of the cylindrical structure by at least 1 mm.

Example 10a is an apparatus according to any examples herein, particularly example 9a, wherein the shield comprises aluminum, alumina, or aluminum nitride.

Example 11a an apparatus comprising: an electrostatic chuck comprising: a plate electrode; and a column structure, the column structure coupled to the plate electrode; a clamp coupled to a base of the column structure; and a shield that extends circumferentially around at least a portion of the column structure and the clamp; and a cap positioned on the shield, wherein the cap comprises an opening.

Example 12a is an apparatus according to any examples herein, particularly example 11a, wherein the shield has a cylindrical structure and wherein the cylindrical structure extends longitudinally beyond a lowermost end of the clamp.

Example 13a is an apparatus according to any examples herein, particularly example 12a, wherein the shield further comprises a base ring around a lowermost portion of the cylindrical structure.

Example 14a is an apparatus according to any examples herein, particularly example 13a, wherein the base ring is coupled with a surface of a chamber housing the electrostatic chuck, the clamp and the shield.

Example 15a is an apparatus according to any examples herein, particularly example 12a, wherein the cylindrical structure extends axially along 30% to 50% of a length of the column structure.

Example 16a is an apparatus according to any examples herein, particularly example 12a, wherein the cylindrical structure extends axially along at least 50% of a length of the column structure.

Example 17a is an apparatus according to any examples herein, particularly example 12a, wherein the cylindrical structure comprises an inner diameter and the column structure comprises a first diameter, and wherein the inner diameter of the cylindrical structure is greater than the first diameter by at least 1 mm.

Example 18a is an apparatus according to any examples herein, particularly example 17a, wherein the clamp comprises an inner diameter, and wherein the inner diameter of the clamp is greater than the first diameter of the column structure by at least 3 mm.

Example 19a is an apparatus according to any examples herein, particularly example 18a, wherein the clamp comprises an outer diameter, wherein the outer diameter of the clamp is less than the inner diameter of the cylindrical structure by at least 1 mm.

Example 20a is an apparatus according to any examples herein, particularly example 19a, wherein the outer diameter is less that the inner diameter of the cylindrical structure by at least 1 mm.

Example 21a is an apparatus according to any examples herein, particularly example 12a, wherein the shield comprises aluminum, alumina or aluminum nitride and the cap comprises aluminum, or alumina.

Example 22a is an apparatus according to any examples herein, particularly example 12a, wherein the cylindrical structure comprises an outer diameter, and wherein the cap does not extend beyond the outer diameter of the cylindrical structure.

Example 23a is an apparatus according to any examples herein, particularly example 17a, wherein the opening comprises a diameter that is smaller than the inner diameter of the cylindrical structure.

Example 24a is an apparatus according to any examples herein, particularly example 19a, wherein the opening comprises a diameter that is smaller than the outer diameter of the clamp, but greater than the inner diameter of the clamp.

Example 25a is an apparatus according to any examples herein, particularly example 18a, wherein the opening comprises a third diameter that is smaller than the inner diameter of the clamp, but greater than the first diameter of the column structure.

Example 26a : An apparatus comprising: an electrostatic chuck comprising: a plate electrode; and a column structure, the column structure coupled below the plate electrode; a clamp coupled to a base of the column structure; a shield that extends circumferentially around at least a portion of the column structure and the clamp; and a disk coupled to the shield, wherein the disk is disposed between the plate electrode and the shield, wherein the disk comprises a first opening, a second opening, and a third opening, wherein the first opening is above the shield, wherein the second opening and the third opening are distributed throughout the disk and wherein the column structure extends through the first opening.

Example 27a is an apparatus according to any examples herein, particularly example 26a, wherein the shield is coupled with a chamber housing the electrostatic chuck and the clamp.

Example 28a is an apparatus according to any examples herein, particularly example 26a, wherein the disk comprises a thickness in a range of 1 mm to 6 mm.

Example 29a is an apparatus according to any examples herein, particularly example 26a, wherein the second opening and third opening have a length of at least 3 mm.

Example 30a is an apparatus according to any examples herein, particularly example 26a, wherein the second opening and the third opening are uniformly spaced apart from each other, and wherein the second opening and the third opening are at an approximately same radii from a center of the disk.

Example 31a is an apparatus according to any examples herein, particularly example 26a, wherein the first opening is circular, and wherein the first opening has a first diameter that is greater than a second diameter of the column structure by at least 1 mm.

Example 32a is an apparatus according to any examples herein, particularly example 26a, wherein the disk is confined within a perimeter of the plate electrode.

Example 33a is an apparatus according to any examples herein, particularly example 26a, wherein the disk comprises a first perimeter and the plate electrode comprises a second perimeter, and wherein the first perimeter is substantially aligned with the second perimeter.

Example 34a is an apparatus according to any examples herein, particularly example 26a, wherein the shield has a cylindrical structure, wherein the cylindrical structure comprises a diameter and the column structure comprises a diameter, and wherein the diameter of the cylindrical structure is greater than the diameter of the column structure by at least 1 mm.

Besides what is described herein, various modifications may be made to the disclosed implementations and implementations thereof without departing from their scope. Therefore, illustrations of implementations herein should be construed as examples only, and not restrictive to the scope of the present disclosure. The scope of the invention should be measured solely by reference to the claims that follow.

What is claimed is:

1. An apparatus comprising:
an electrostatic chuck comprising:
a plate electrode; and
a column structure coupled with the plate electrode;
a disk coupled with the electrostatic chuck, the disk comprising:
a first hole which is substantially in a center of the disk; and
a second hole and a third hole distributed through the disk, wherein a portion of the column structure extends through the first hole; and
a first retention structure and a second retention structure, wherein the first retention structure comprises:
a first shaft and a first nut coupled with the first shaft and the disk; and
a second nut coupled with a second shaft and the disk, wherein the first shaft extends through the second hole, wherein the second shaft extends through the third hole, and wherein the first shaft and the second shaft coupled with a surface of the plate electrode.

2. The apparatus of claim 1, wherein the disk has a thickness between 6 cm and 1.5 cm.

3. The apparatus of claim 1, wherein the second hole and the third hole have a length between 12 mm and 50 mm, wherein the apparatus further comprises a fourth hole, wherein the fourth hole has a length between 12 mm and 50 mm, wherein the second hole, the third hole, and the fourth hole are uniformly spaced apart from each other and are at an approximately same radius from the center of the disk.

4. The apparatus of claim 1, wherein the column structure further comprises:
a first stem connected to the plate electrode;
a second stem coupled with the first stem;
a ring directly between the first stem and the second stem; and
a clamp coupled with the first stem and the second stem, wherein the first hole has a first diameter, wherein the clamp has a second inner diameter, wherein the first diameter is greater than the second inner diameter by at least 1 mm, wherein the first stem has a third diameter, and wherein the second inner diameter is greater than the third diameter by at least 1 mm.

5. The apparatus of claim 1, wherein the first shaft and the second shaft comprise:
a hollow core with a variable outer diameter;
a first threaded portion at a first end;
a second threaded portion; and
a barrel between the first threaded portion and the second threaded portion, wherein the hollow core extends a length of the first shaft or the second shaft, wherein the first shaft and the second shaft are not in contact with the disk, wherein the barrel has a length of at least 3 mm, and wherein the second threaded portion is adjacent to the disk.

6. The apparatus of claim 5, wherein the first nut and the second nut comprise a first portion and a second portion, wherein the first portion comprises a first outer diameter, and wherein the second portion comprises a second outer diameter, wherein the second hole and the third hole comprise a length that is greater than the second outer diameter by at least 2 mm.

7. The apparatus of claim 1, wherein the second hole and the third hole comprise a first tapered sidewall and a second tapered sidewall, wherein the first tapered sidewall extends from a first surface to substantially half a thickness of the disk, and wherein the second tapered sidewall extends from half the thickness of the disk to a second surface, and wherein the first tapered sidewall and the second tapered sidewall are oppositely tapered.

8. The apparatus of claim 5, wherein first and second portions of the first nut and the second nut extend through the disk, wherein the first shaft the second shaft comprise a first material, and wherein the first nut the second nut comprise a second material, wherein the first threaded portion extends partially into the plate electrode through a bottom surface of the plate electrode.

9. The apparatus of claim 8, wherein the first shaft comprises a first hollow core which extends along a first length of the first shaft, and wherein the second shaft comprises a second hollow core that extends along a second length of the second shaft, wherein the first shaft and the second shaft further comprise a ring between the second threaded portion and the barrel, wherein portions of the ring are in contact with the disk, wherein the ring comprises a third outer diameter that is greater than a length of the first hole and the second hole.

10. The apparatus of claim 1, wherein the disk does not extend outside a perimeter of the plate electrode, wherein the disk comprises a first perimeter, wherein the plate electrode comprises a second perimeter, and wherein the first perimeter is substantially aligned with the second perimeter.

11. An apparatus comprising:
an electrostatic chuck comprising:
a plate electrode; and
a column structure coupled to the plate electrode;
a clamp coupled to a base of the column structure; and
a shield that extends circumferentially around at least a portion of the clamp and the column structure.

12. The apparatus of claim 11, wherein the shield has a cylindrical structure and wherein the cylindrical structure extends longitudinally beyond a lowermost end of the clamp.

13. The apparatus of claim 12, wherein the shield further comprises a base ring around a lowermost portion of the cylindrical structure.

14. The apparatus of claim 13, wherein the electrostatic chuck is situated within a chamber, and wherein the base ring is coupled with a surface of the chamber.

15. The apparatus of claim 11, wherein the shield extends axially along 30%-50% of a length of the column structure.

16. The apparatus of claim 11, wherein the shield extends axially along at least 50% of a length of the column structure.

17. The apparatus of claim 12, wherein the cylindrical structure comprises an inner diameter and the column structure comprises a first diameter, and wherein the inner diameter of the cylindrical structure is greater than the first diameter of the column structure by at least 1 mm.

18. The apparatus of claim 17, wherein the clamp comprises an inner diameter, and wherein the inner diameter of the clamp is greater than the first diameter of the column structure by at least 3 mm.

19. The apparatus of claim 17, wherein the clamp comprises an outer diameter that is less than the inner diameter of the cylindrical structure by at least 1 mm.

20. The apparatus of claim 11, wherein the shield comprises aluminum, alumina, or aluminum nitride.
